(19) United States
(12) Patent Application Publication
(10) Pub. No.: US 2026/0101627 A1
(43) Pub. Date: Apr. 9, 2026

(54) DETECTION DEVICE

(71) Applicant: Japan Display Inc., Tokyo (JP)

(72) Inventors: Yasushi TOMIOKA, Tokyo (JP); Yuta HAGA, Tokyo (JP)

(21) Appl. No.: 19/404,543

(22) Filed: Dec. 1, 2025

Related U.S. Application Data
(63) Continuation of application No. PCT/JP2024/019576, filed on May 28, 2024.

(30) Foreign Application Priority Data
Sep. 22, 2023 (JP) 2023-158247
Jun. 2, 2023 (JP) 2023-091821

(51) Int. Cl. H10K 39/32; H10K 30/40; H10K 30/60

(52) U.S. Cl. CPC H10K 39/32; H10K 30/40; H10K 30/60

(57) ABSTRACT

According to an aspect, a detection device includes: an optical sensor comprising a plurality of light-receiving elements configured to receive light; and a front light that is located on an object to be detected side of the optical sensor and comprises a light guide film and a plurality of light sources configured to emit light to a first side surface of the light guide film. A wire-grid polarizer configured to separate the light incident from the light source into first polarized light and second polarized light is located between the optical sensor and the front light.

### CROSS-REFERENCE TO RELATED APPLICATION

This application claims the benefit of priority from Japanese Patent Application No. 2023-091821 filed on June 2, 2023, and Japanese Patent Application No. 2023-158247 filed on September 22, 2023 and International Patent Application No. PCT/JP2024/019576 filed on May 28, 2024, the entire contents of which are incorporated herein by reference.

### BACKGROUND

### 1. Technical Field

What is disclosed herein relates to a detection device.

### 2. Description of the Related Art

Optical sensors capable of detecting fingerprint patterns and vein patterns are known (for example, Japanese Patent Application Laid-open Publication No. 2019-045503 (JP-A-2019-045503) and Japanese Patent Application Laid-open Publication No. H11-120324 (JP-A-H11-120324)). The optical sensors described in JP-A-2019-045503 and JP-A-H11-120324 are each provided with a front light on the front side of a plurality of photodiodes.

When such a detection device is used on the thick skin of, for example, a wrist, light-receiving elements near the center of the optical sensor far from a light source may cause a decrease in contrast of detection due to insufficiency in light intensity.

For the foregoing reasons, there is a need for a detection device that can uniformly emit light to the entire optical sensor surface and obtain better detection accuracy.

### SUMMARY

According to an aspect, a detection device includes: an optical sensor comprising a plurality of light-receiving elements configured to receive light; and a front light that is located on an object to be detected side of the optical sensor and comprises a light guide film and a plurality of light sources configured to emit light to a first side surface of the light guide film. A wire-grid polarizer configured to separate the light incident from the light source into first polarized light and second polarized light is located between the optical sensor and the front light.

### BRIEF DESCRIPTION OF THE DRAWINGS

FIG. 1 is a perspective view schematically illustrating a detection device according to a first embodiment of the present disclosure;

FIG. 2 is a sectional view schematically illustrating a section of the detection device according to the first embodiment;

FIG. 3 is an explanatory diagram illustrating transmittance versus an acceptance angle of an optical filter layer according to the first embodiment;

FIG. 4A is a perspective view schematically illustrating a wire-grid polarizer according to the first embodiment;

FIG. 4B is a perspective view schematically illustrating the wire-grid polarizer that has a different wire direction from that of FIG. 4A;

FIG. 5 is a plan view schematically illustrating the detection device according to the first embodiment;

FIG. 6 is a block diagram illustrating a configuration example of the detection device according to the first embodiment;

FIG. 7 is a circuit diagram illustrating a light-receiving element;

FIG. 8 is a plan view schematically illustrating the light-receiving element of the detection device according to the first embodiment;

FIG. 9 is a sectional view taken along IX-IX' in FIG. 8;

FIG. 10 depicts explanatory diagrams illustrating a relation between incident dependence of transmittance of a light guide film and incident dependence of reflectance of the wire-grid polarizer in the first embodiment;

FIG. 11 is a sectional view schematically illustrating a section of a detection device according to a second embodiment of the present disclosure;

FIG. 12 depicts explanatory diagrams illustrating the relation between the incident dependence of the transmittance of the light guide film and the incident dependence of the reflectance of the wire-grid polarizer in the second embodiment;

FIG. 13 is a perspective view schematically illustrating an example of a detection device according to a third embodiment of the present disclosure;

FIG. 14 is a perspective view schematically illustrating a different example from the detection device of FIG. 13;

FIG. 15 is a perspective view schematically illustrating a different example from the detection device of FIG. 14;

FIG. 16 is a plan view schematically illustrating a detection device according to a fourth embodiment of the present disclosure;

FIG. 17 is a perspective view schematically illustrating a detection device according to a fifth embodiment of the present disclosure;

FIG. 18 is a sectional view schematically illustrating a section of a detection device according to a sixth embodiment of the present disclosure;

FIG. 19 is a perspective view schematically illustrating the detection device according to the sixth embodiment;

FIG. 20 is a sectional view schematically illustrating a section of a detection device according to a seventh embodiment of the present disclosure;

FIG. 21 is a plan view schematically illustrating the detection device according to the seventh embodiment;

FIG. 22 is an explanatory diagram illustrating transmittance of a high refractive index waveguide layer versus an incident angle thereon in the seventh embodiment;

FIG. 23 is a sectional view schematically illustrating a detection device according to an eighth embodiment of the present disclosure;

FIG. 24 is an explanatory diagram illustrating the transmittance of the light guide film versus the incident angle thereon in the eighth embodiment;

FIG. 25 is a sectional view schematically illustrating an example of the light-receiving element according to the eighth embodiment;

FIG. 26 is a sectional view schematically illustrating a different example from the light-receiving element of FIG. 25;

FIG. 27 is a sectional view schematically illustrating a different example from the light-receiving element of FIG. 26;

FIG. 28 is a sectional view schematically illustrating a section of a detection device according to a ninth embodiment of the present disclosure;

FIG. 29 depicts explanatory diagrams explaining the transmittance of the light guide film versus the incident angle thereon in the ninth embodiment;

FIG. 30 depicts explanatory diagrams explaining the transmittance of the light guide film versus the incident angle thereon, which is different from that of the detection device of FIG. 29;

FIG. 31 is a sectional view schematically illustrating a detection device according to a tenth embodiment of the present disclosure;

FIG. 32 depicts explanatory diagrams illustrating a relation between the transmittance of the light guide film versus the incident angle and the transmittance of a protective film versus the incident angle in the tenth embodiment;

FIG. 33 is a sectional view schematically illustrating a detection device according to an eleventh embodiment of the present disclosure; and

FIG. 34 is a perspective view schematically illustrating a detection device according to a twelfth embodiment of the present disclosure.

### DETAILED DESCRIPTION

The following describes modes (embodiments) for carrying out the disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present specification and the drawings, and detailed description thereof may not be repeated where appropriate.

In the embodiments of the present disclosure, in expressing an aspect of disposing another structure on or above a certain structure, a case of simply expressing "on" includes both a case of disposing the other structure immediately on the certain structure so as to contact the certain structure and a case of disposing the other structure above the certain structure with still another structure interposed therebetween, unless otherwise specified.

### First Embodiment

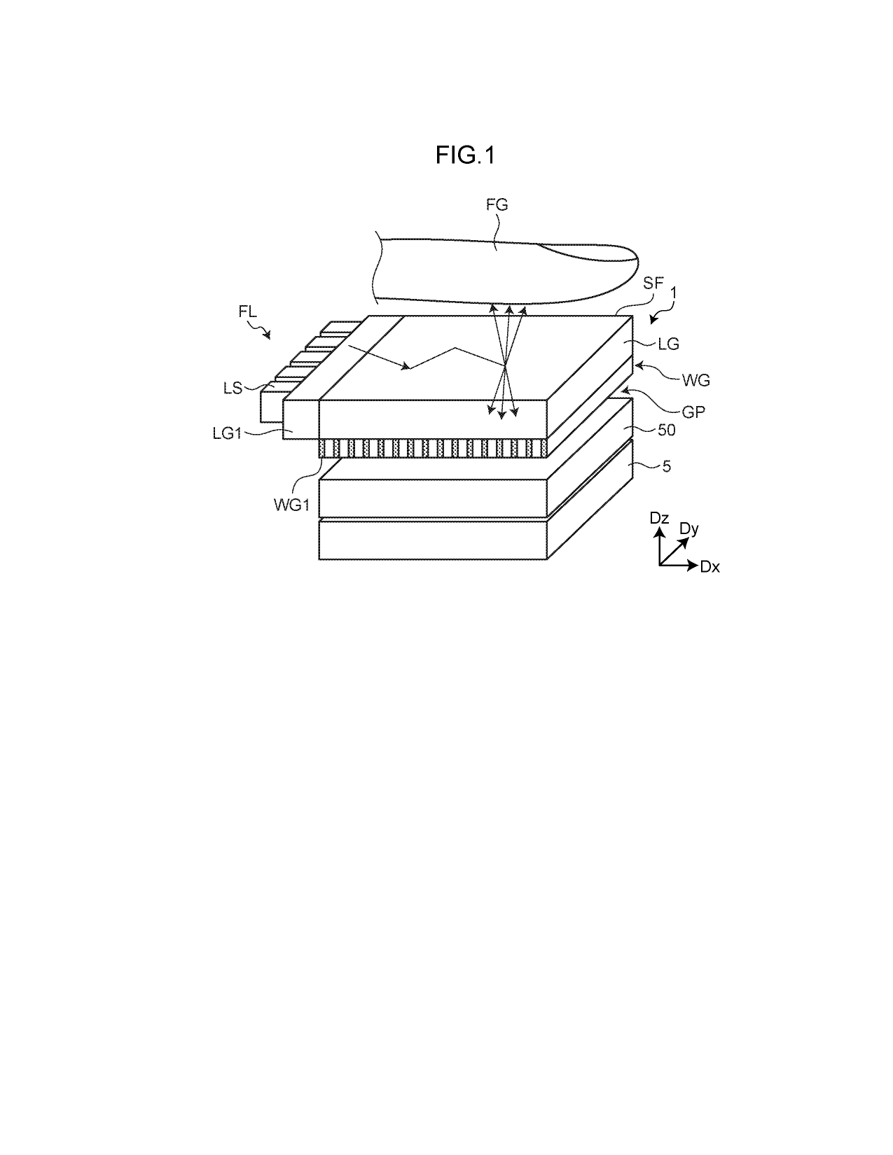

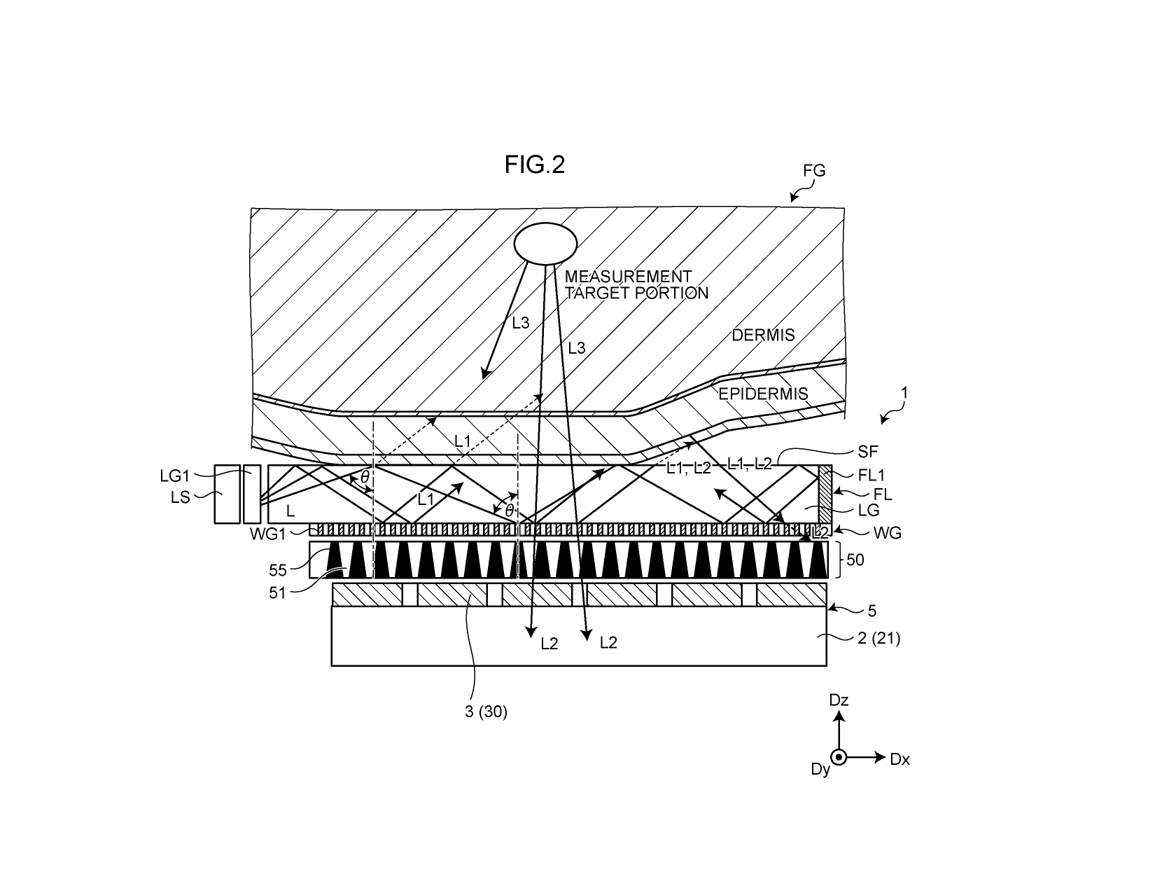

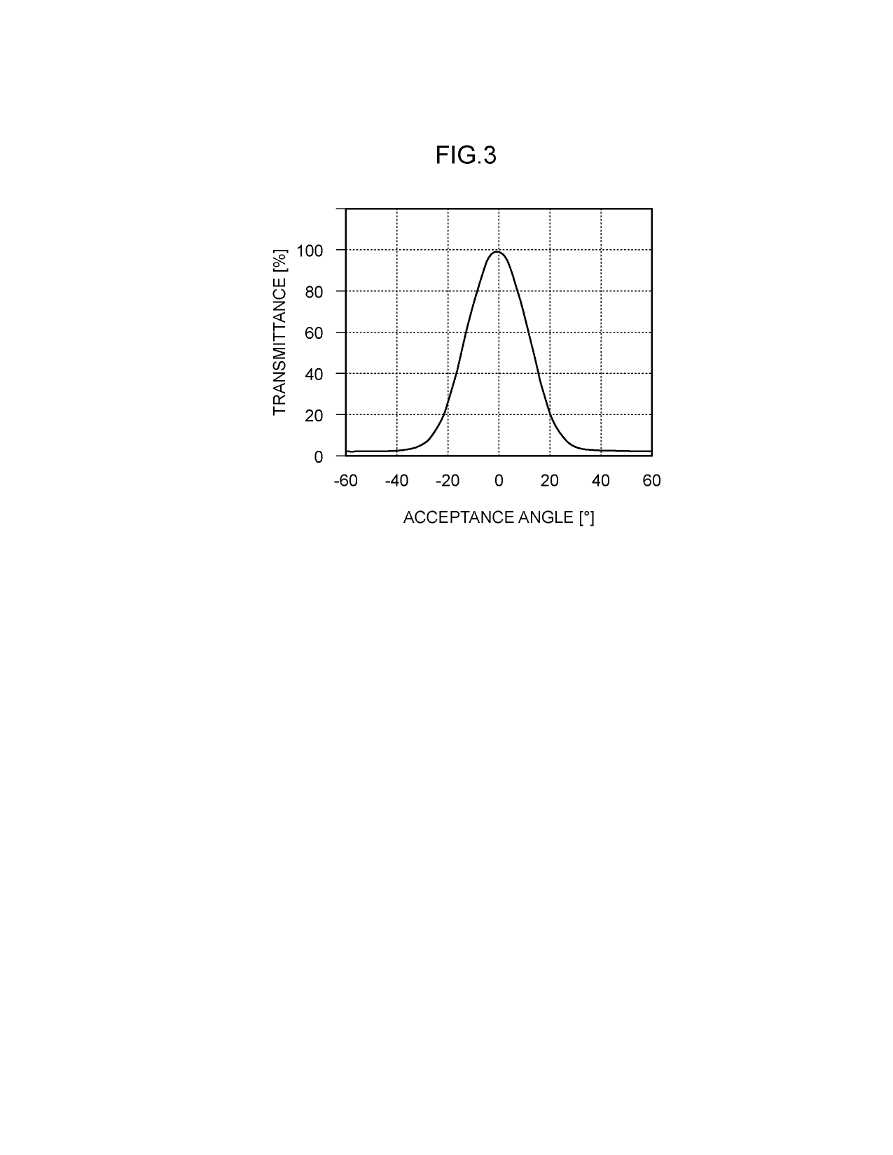

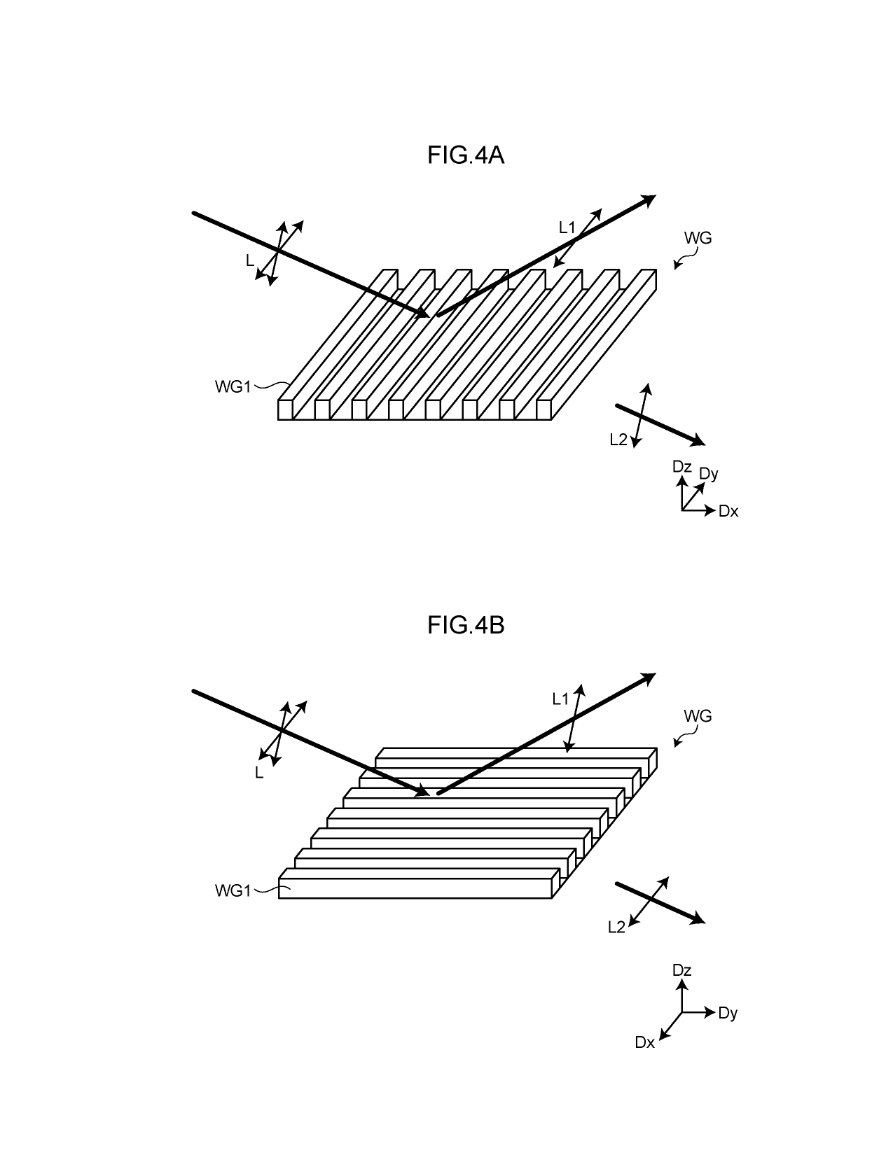

FIG. 1 is a perspective view schematically illustrating a detection device according to a first embodiment of the present disclosure. FIG. 2 is a sectional view schematically illustrating a section of the detection device according to the first embodiment. FIG. 3 is an explanatory diagram illustrating transmittance versus an acceptance angle of an optical filter layer according to the first embodiment. FIG. 4A is a perspective view schematically illustrating a wire-grid polarizer according to the first embodiment. FIG. 4B is a perspective view schematically illustrating the wire-grid polarizer that has a different wire direction from that of FIG. 4A. As illustrated in FIGS. 1 and 2, a detection device 1 includes an optical sensor 5, an optical filter layer 50, a wire-grid polarizer plate WG, and a front light FL. The optical filter layer 50, the wire-grid polarizer WG1, and the front light FL are stacked in this order on the optical sensor 5.

The front light FL includes a light guide film LG and a light source LS facing a side of the light guide film LG. The front light FL is located on an object to be detected FG side of the optical sensor 5 and includes the light guide film LG, a reflector plate FL1, a light entrance LG1, and a plurality of the light sources LS. The object to be detected FG is, for example, a palm, a wrist, a finger, or the like.

The light sources LS are arranged along one side surface of the light guide film LG. Each of the light sources LS emits light to a first side surface of the light guide film LG through the light entrance LG1. For example, an inorganic light-emitting diode (LED), an organic electroluminescent (EL) diode (organic light-emitting diode (OLED)), a semiconductor laser diode (LD), or the like is used as each of the light sources LS. Light sources LS emit light having predetermined wavelengths. In the present embodiment, the light sources LS includes a plurality of light sources so as to be capable of emitting infrared light, near-infrared light, and visible light from red, green, to blue light.

The reflector plate FL1 is located on a side surface of the light guide film LG opposite the light sources LS or on a side surface of the light guide film LG where the light sources LS are not provided. The reflector plate FL1 reflects light L propagating in the light guide film LG toward a side surface on the light source LS side.

The light entrance LG1 is a base member provided to efficiently guide the light emitted from the light sources LS into the light guide film LG. The light entrance LG1 has a light-transmitting property, and made, for example, of an optical resin.

As illustrated in FIG. 2, the optical sensor 5 includes a substrate 21 and a light-receiving element 3. The optical sensor 5 is located on the opposite side to the object to be detected side of the front light FL, and the optical sensor 5 overlaps a detection surface SF of the light guide film LG as viewed from the object to be detected FG side of the light guide film LG.

The light guide film LG is a film that is light-transmitting and formed of a polymer compound, such as triacetylcellulose (TAC).

The refractive index of the light guide film LG is 1.487, for example. The refractive index of the epidermis of the object to be detected FG is 1.43, for example. The refractive index of the dermis of the object to be detected FG is 1.396, for example.

The size of the light guide film LG is from 50 μm to 300 μm, for example.

A first direction Dx is one direction in a plane parallel to the substrate 21. A second direction Dy is one direction in the plane parallel to the substrate 21 and is a direction orthogonal to the first direction Dx. The second direction Dy may non-orthogonally intersect the first direction Dx. A third direction Dz is a direction orthogonal to the first direction Dx and the second direction Dy and is a direction normal to the substrate 21.

The optical filter layer 50 is located between the light-receiving element 3 and the wire-grid polarizer plate WG. The optical filter layer 50 is an optical element that transmits, toward a photodiode 30, components of light reflected by the object to be detected FG or the like that travel in the third direction Dz and attenuates other components thereof traveling in other directions. The optical filter layer 50 is also called collimating apertures or a collimator. The optical filter layer 50 is provided on the object to be detected FG side of the light-receiving element 3 and faces the light-receiving element 3. The optical filter layer 50 has a plurality of light guide paths 51 and a light blocker 55 provided around the light guide paths 51. At least some of the light guide paths 51 overlap the photodiodes 30. The light blocker 55 has higher optical absorbance than the light guide paths 51.

The optical filter layer 50 is bonded to the optical sensor 5 with an optical resin (not illustrated). A space may be present between the optical filter layer 50 and the optical sensor 5.

As illustrated in FIG. 3, the narrower the acceptance angle at which the optical filter layer 50 accepts light, the higher the resolution of imaging. As a result, fingerprints or the like can be imaged. The acceptance angle of the optical filter layer 50 is an angle at which light enters the optical filter layer 50.

As illustrated in FIGS. 1 and 2, the wire-grid polarizer plate WG is located between the optical filter layer 50 and the front light FL.

As illustrated in FIGS. 1 and 4A, the wire-grid polarizer plate WG includes a plurality of wire-grid polarizers WG1 and a light guide film LG that supports the wire-grid polarizers WG1. The wire-grid polarizers WG1 are provided on the light guide film LG, being arranged at predetermined intervals in the first direction Dx, extending along the second direction Dy, and projecting in the third direction Dz toward the optical sensor 5.

The wire-grid polarizers WG1 are formed of a wire grid using metal nanowires. The material of the wire-grid polarizers WG1 is an aluminum alloy, for example.

As illustrated in FIG. 4A, each of the wire-grid polarizers WG1 separates the light L incident from the light source LS into the first polarized light L1 and the second polarized light L2. The first polarized light L1 oscillates parallel to the wire direction of the wire-grid polarizer WG1, and the second polarized light L2 oscillates orthogonally to the wire direction of the wire-grid polarizer WG1. When the light L has entered the wire-grid polarizer WG1 from a direction orthogonal to the wire-grid polarizer WG1 (direction orthogonal to the second direction Dy), the first polarized light L1 is reflected by the wire-grid polarizer WG1, and the second polarized light L2 is transmitted through the wire-grid polarizer WG1. The wire direction refers to the direction in which the wire of the wire-grid polarizer WG1 extends. In the present embodiment, the first polarized light L1 is the s-polarization component and the second polarized light L2 is the p-polarization component. Depending on the incident direction of the light L, the first polarized light L1 may be the p-polarization component and the second polarized light L2 may be the s-polarization component.

The wire direction of the wire-grid polarizer WG1 can be not only the first direction Dx illustrated in FIG. 4A, but also the second direction Dy illustrated in FIG. 4B.

As illustrated in FIG. 4B, when the light L has entered the wire-grid polarizer WG1 from a direction parallel to the wire-grid polarizer WG1 (direction parallel to the second direction Dy), the wire-grid polarizer WG1 reflects the first polarized light L1, and transmits and emits the second polarized light L2 toward the light-receiving element 3. Thus, regardless of the incident direction of the light L, the first polarized light L1 that oscillates parallel to the wire direction of the wire-grid polarizer WG1 is always reflected by the wire-grid polarizer WG1, and the second polarized light L2 that oscillates orthogonal to the wire direction of the wire-grid polarizer WG1 is always transmitted through the wire-grid polarizer WG1. In that case, the light guide film LG propagates the first polarized light L1, and transmits and emits the second polarized light L2 toward the light-receiving element 3.

A gap GP is provided between the wire-grid polarizer plate WG and the optical filter layer 50. The wire-grid polarizer plate WG is bonded to the optical filter layer 50, for example, with an optical resin (not illustrated) in the gap GP. The gap GP may be an air layer, for example.

As illustrated in FIG. 2, the light from the light sources LS is emitted into the light guide film LG, and the first polarized light L1 reflected by the wire-grid polarizer WG1 propagates in the light guide film LG. When the object to be detected FG contacts the detection surface SF, the first polarized light L1 reaches the epidermis of the object to be detected FG. The second polarized light L2 transmitted through the wire-grid polarizer WG1 is blocked from entering the light-receiving element 3 when the magnitude of the acceptance angle of the optical filter layer 50 is larger than approximately 20° (refer to FIG. 3), but enters the light-receiving element 3 through the optical filter layer 50 when the magnitude of the acceptance angle of the optical filter layer 50 is equal to or smaller than approximately 20°. Thus, the optical sensor 5 can detect the light. The optical sensor 5 can, for example, detect information on the skin and the like of the object to be detected FG based on the light emitted from the light sources LS. The optical sensor 5 may detect various types of information (biometric information), such as shapes of blood vessels, pulsation, and pulse waves.

Further, when the first polarized light L1 reaches a measurement target portion at a deeper part of the dermis (for example, blood vessels or the like), the polarization is eliminated and becomes backscattered light L3. When the backscattered light L3 from the measurement target portion enters the wire-grid polarizer WG1, the second polarized light L2 components are transmitted through the wire-grid polarizer WG1. At this time, since light enters the optical filter layer 50 side when the magnitude of the acceptance angle of the optical filter layer 50 is approximately 20° or smaller, the second polarized light L2 enters the light-receiving element 3 through the optical filter layer 50.

As a result of the above, good polarization separation also reduces the intensity of light leaking from the light guide film LG, allowing the first polarized light L1 to uniformly irradiate the entire object to be detected FG side of the optical sensor 5, and allowing better detection accuracy to be obtained.

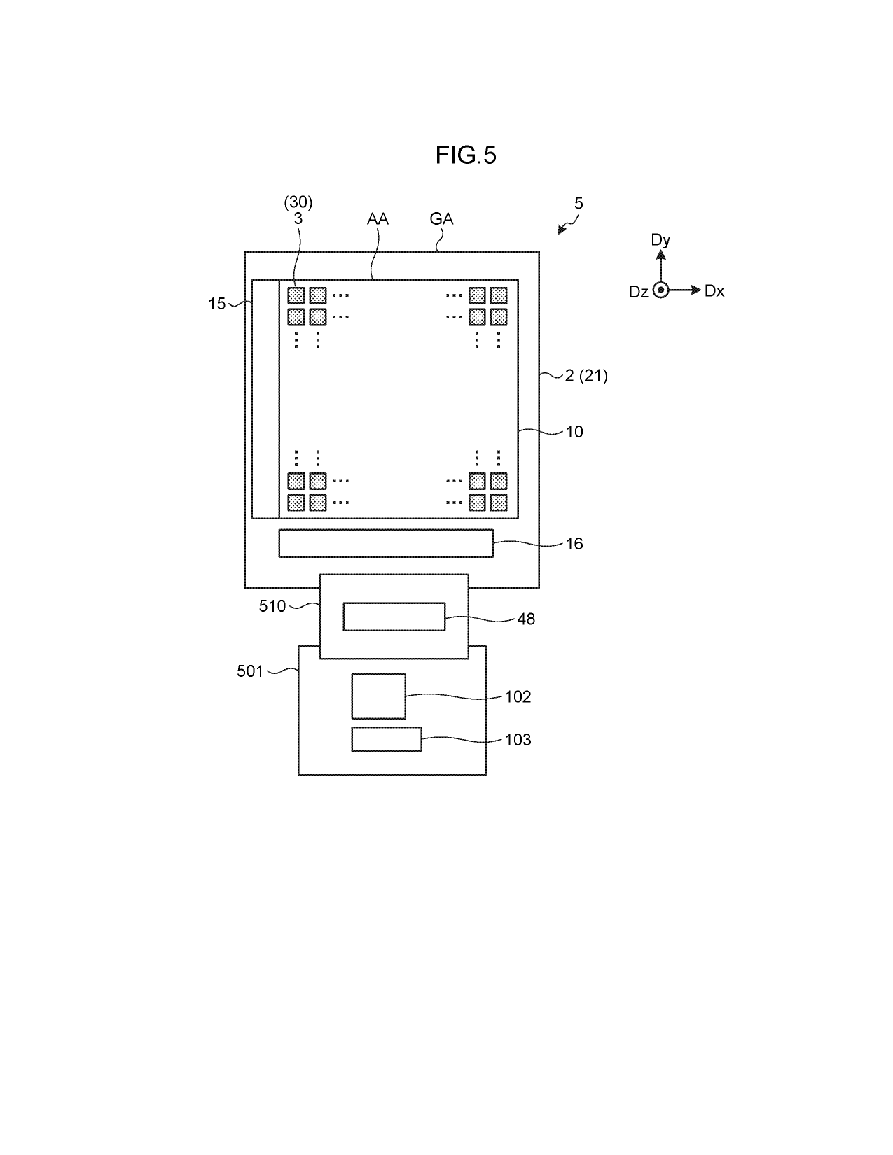

FIG. 5 is a plan view schematically illustrating the detection device according to the first embodiment. As illustrated in FIG. 5, the optical sensor 5 includes an array substrate 2 (substrate 21), the light-receiving element 3, a scan line drive circuit 15, a signal line selection circuit 16, a detection circuit 48, a control circuit 102, and a power supply circuit 103.

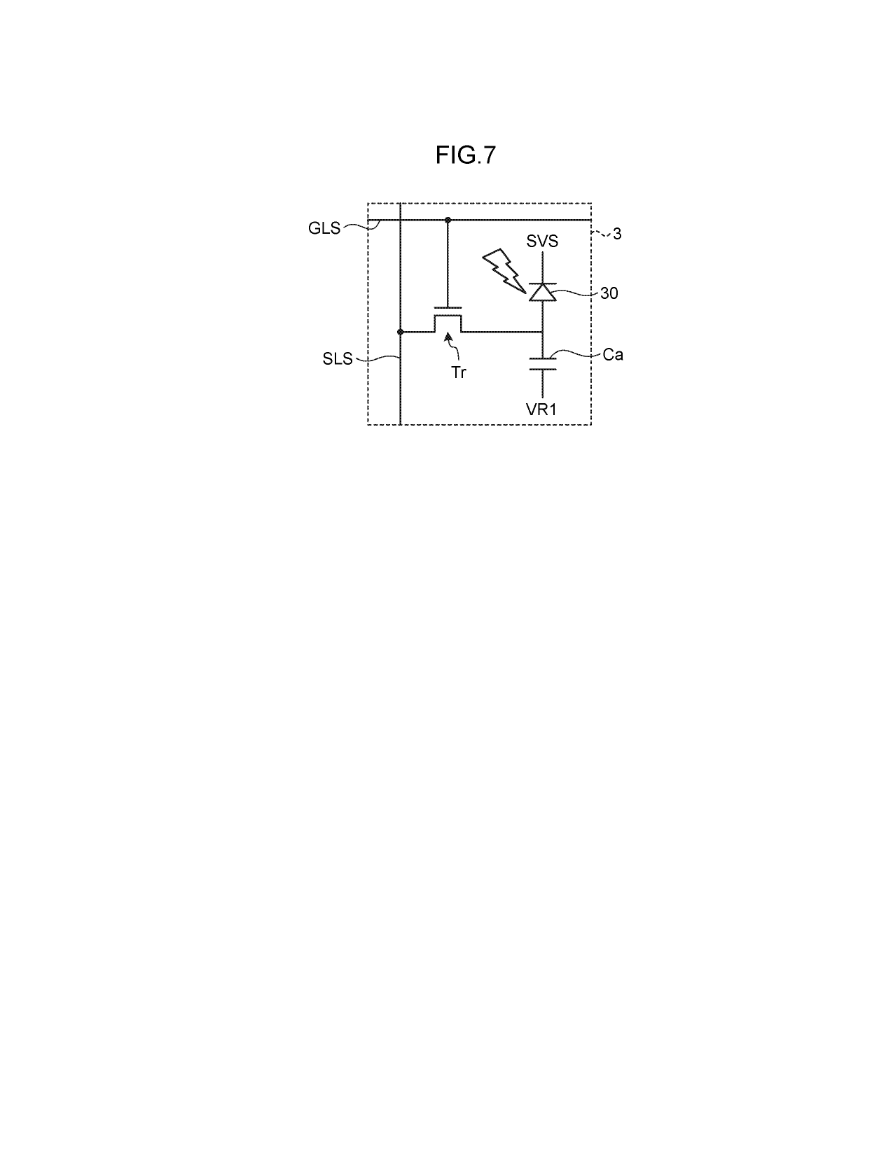

The substrate 21 is electrically coupled to a control substrate 501 through a wiring substrate 510. The wiring substrate 510 is, for example, a flexible printed circuit board or a rigid circuit board. The wiring substrate 510 is provided with the detection circuit 48. The control substrate 501 is provided with the control circuit 102 and the power supply circuit 103. The control circuit 102 is a field-programmable gate array (FPGA), for example. The control circuit 102 supplies control signals to a sensor 10, the scan line drive circuit 15, and the signal line selection circuit 16 to control detection operations of the sensor 10. The power supply circuit 103 supplies voltage signals including, for example, a power supply potential SVS and a reference potential VR1 (refer to FIG. 7) to the sensor 10, the scan line drive circuit 15, and the signal line selection circuit 16. While the first embodiment illustrates the case of locating the detection circuit 48 on the wiring substrate 510, the present disclosure is not limited to this case. The detection circuit 48 may be located on the substrate 21.

The substrate 21 has a detection area AA and a peripheral area GA. The detection area AA is an area provided with a plurality of the light-receiving elements 3 included in the sensor 10. The peripheral area GA is an area outside the detection area AA and is an area not provided with the light-receiving elements 3. That is, the peripheral area GA is an area between the outer perimeter of the detection area AA and the outer edges of the substrate 21.

Each of the light-receiving elements 3 of the sensor 10 is a photosensor including the photodiode 30 as a sensor element. Each of the photodiodes 30 outputs an electric signal corresponding to light emitted thereto. Specifically, the photodiode 30 is a positive-intrinsic-negative (PIN) photodiode or an organic photodiode (OPD) using an organic semiconductor. The light-receiving elements 3 are arranged in a matrix having a row-column configuration in the detection area AA. The photodiodes 30 included in the light-receiving elements 3 perform detection in response to gate drive signals supplied from the scan line drive circuit 15. Each of the photodiodes 30 outputs the electrical signal corresponding to the light emitted thereto as a detection signal Vdet to the signal line selection circuit 16. The detection device 1 detects information on the object to be detected FG based on the detection signals Vdet from the photodiodes 30.

The scan line drive circuit 15 and the signal line selection circuit 16 are provided in the peripheral area GA. Specifically, the scan line drive circuit 15 is provided in an area extending along the second direction Dy in the peripheral area GA. The signal line selection circuit 16 is provided in an area extending along the first direction Dx in the peripheral area GA and is provided between the sensor 10 and the detection circuit 48.

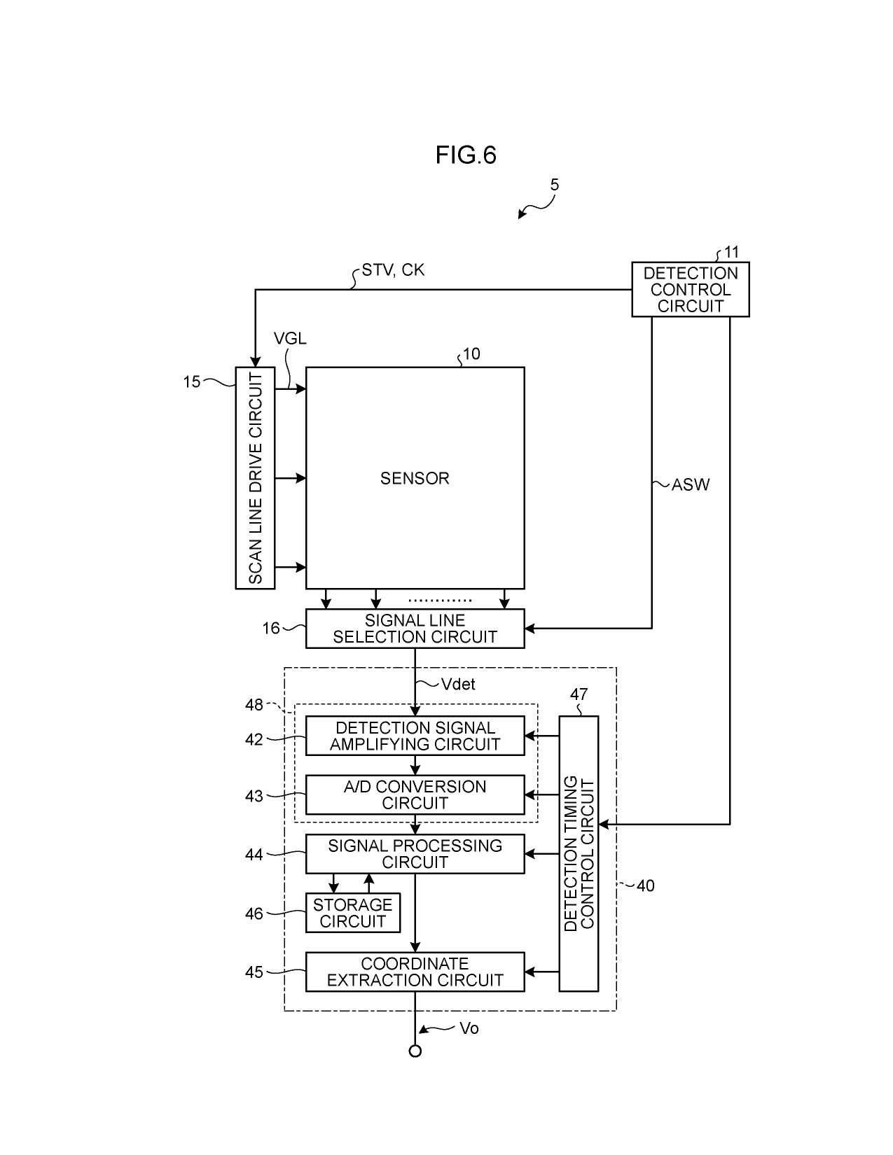

FIG. 6 is a block diagram illustrating a configuration example of the detection device according to the first embodiment. As illustrated in FIG. 6, the detection device 1 further includes a detection control circuit 11 and a detector (detection processing circuit) 40. The control circuit 102 includes one, some, or all functions of the detection control circuit 11. The control circuit 102 also includes one, some, or all functions of the detector 40 other than those of the detection circuit 48.

The detection control circuit 11 is a circuit that supplies respective control signals to the scan line drive circuit 15, the signal line selection circuit 16, and the detector 40 to control operations of these components. The detection control circuit 11 supplies various control signals including, for example, a start signal STV and a clock signal CK to the scan line drive circuit 15. The detection control circuit 11 also supplies various control signals including, for example, a selection signal ASW to the signal line selection circuit 16.

The scan line drive circuit 15 is a circuit that drives a plurality of scan lines GLS (refer to FIG. 7) based on the various control signals. The scan line drive circuit 15 sequentially or simultaneously selects the scan lines GLS, and supplies gate drive signals VGL to the selected scan lines GLS. Through this operation, the scan line drive circuit 15 selects the photodiodes 30 coupled to the scan lines GLS.

The signal line selection circuit 16 is a switch circuit that sequentially or simultaneously selects a plurality of output signal lines SLS (refer to FIG. 7). The signal line selection circuit 16 is a multiplexer, for example. The signal line selection circuit 16 couples the selected output signal lines SLS to the detection circuit 48 based on the selection signal ASW supplied from the detection control circuit 11. Through this operation, the signal line selection circuit 16 outputs the detection signals Vdet of the photodiodes 30 to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 to operate synchronously based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 is a circuit that amplifies the detection signal Vdet, and is an integrating circuit, for example. The A/D conversion circuit 43 converts analog signals output from the detection signal amplifying circuit 42 into digital signals.

The signal processing circuit 44 is a logic circuit that detects predetermined physical quantities received by the sensor 10 based on output signals of the detection circuit 48. The signal processing circuit 44 can detect, based on the signals from the detection circuit 48, information based on the light reflected by the object to be detected FG when the object to be detected FG is in contact with or in proximity to the detection surface SF. The signal processing circuit 44 can also detect other biometric information, for example, on the pulse waves, the pulsation, and a blood oxygen saturation level based on the signals from the detection circuit 48.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the object to be detected FG (for example, detected positions of the blood vessels in the palm or the wrist) when the contact or proximity of the object to be detected FG is detected by the signal processing circuit 44. The coordinate extraction circuit 45 combines the detection signals Vdet output from the respective light-receiving elements 3 of the sensor 10 to generate two-dimensional information indicating the shape of the asperities on the surface of the skin and two-dimensional information indicating a vascular image. The coordinate extraction circuit 45 may output the detection signals Vdet as sensor outputs Vo instead of calculating the detected coordinates.

The following describes a circuit configuration example of the optical sensor 5. FIG. 7 is a circuit diagram illustrating the light-receiving element of the optical sensor 5. As illustrated in FIG. 7, the light-receiving element 3 includes the photodiode 30, a capacitive element Ca, and a first transistor Tr. The first transistor Tr is provided correspondingly to the photodiode 30. The first transistor Tr is configured as a thin-film transistor, and in this example, configured as an n-channel metal oxide semiconductor (MOS) thin-film transistor (TFT). The gate of the first transistor Tr is coupled to a corresponding one of the scan lines GLS. The source of the first transistor Tr is coupled to a corresponding one of the output signal lines SLS. The drain of the first transistor Tr is coupled to the anode of the photodiode 30 and the capacitive element Ca.

The cathode of the photodiode 30 is supplied with the power supply potential SVS from the power supply circuit 103. The capacitive element Ca is supplied with the reference potential VR1 serving as an initial potential of the capacitive element Ca from the power supply circuit 103.

When the light-receiving element 3 is irradiated with light, a current corresponding to the light intensity flows through the photodiode 30. As a result, an electric charge is stored in the capacitive element Ca. Turning on the first transistor Tr causes a current corresponding to the electric charge stored in the capacitive element Ca to flow through the output signal line SLS. The output signal line SLS is coupled to the detection circuit 48 via the signal line selection circuit 16. Thus, the detection device 1 can detect a signal corresponding to the intensity of the light received by the photodiode 30 for each of the light-receiving elements 3.

While FIG. 7 illustrates one of the light-receiving elements 3, the scan line GLS and the output signal line SLS are coupled to a plurality of the light-receiving elements 3. Specifically, the scan line GLS extends in the first direction Dx (refer to FIG. 2) and is coupled to the light-receiving elements 3 arranged in the first direction Dx. The output signal line SLS extends in the second direction Dy and is coupled to the light-receiving elements 3 arranged in the second direction Dy.

The first transistor Tr is not limited to the n-type TFT and may be configured as a p-type TFT. The light-receiving element 3 may be provided with a plurality of transistors corresponding to each of the photodiodes 30.

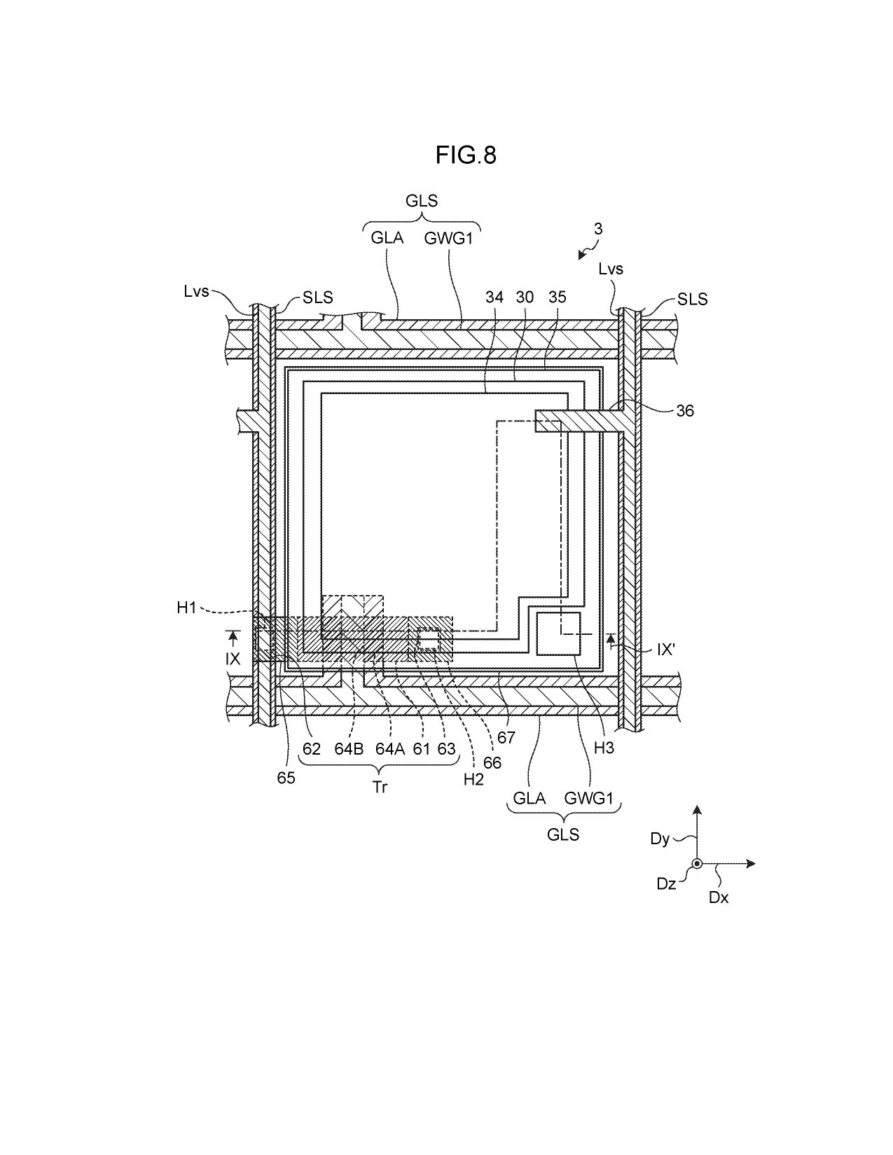

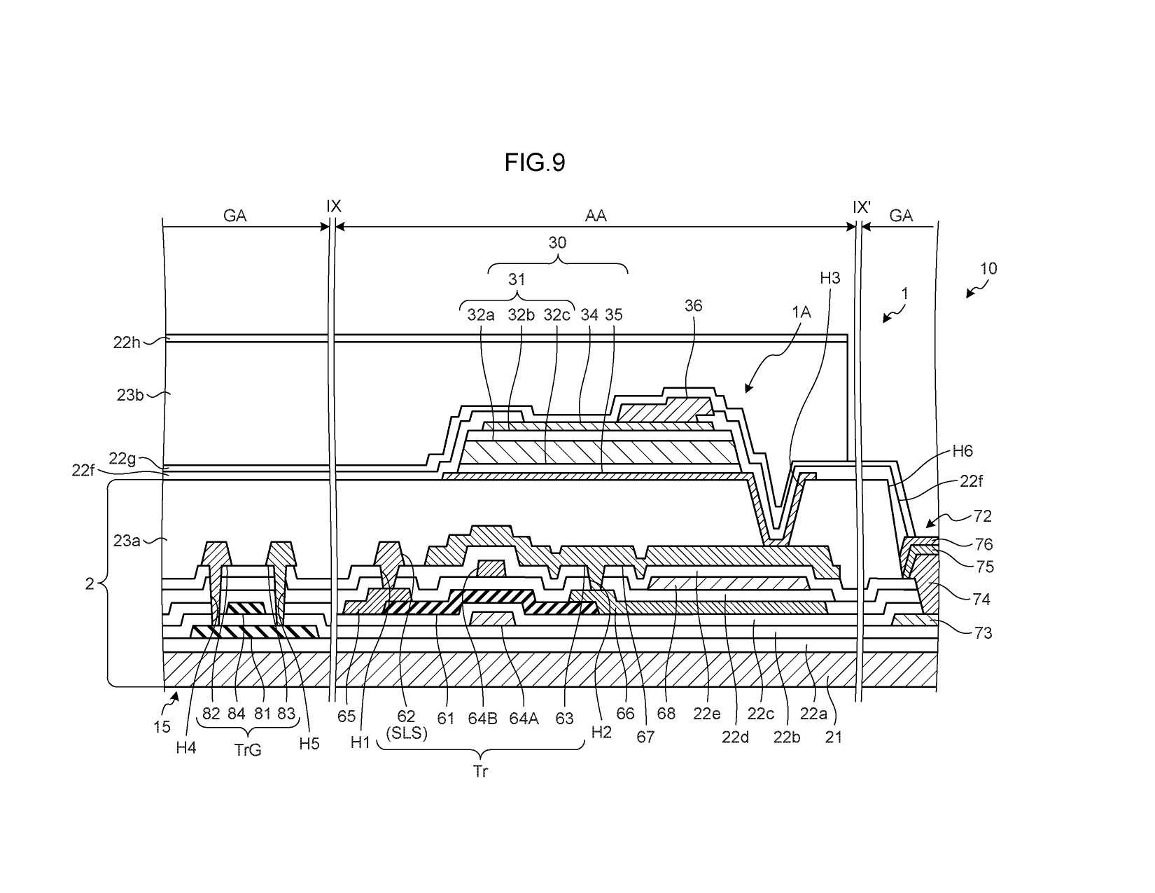

The following describes a detailed configuration of the detection device 1. FIG. 8 is a plan view schematically illustrating the light-receiving element of the detection device according to the first embodiment. As illustrated in FIG. 8, the light-receiving element 3 is an area surrounded by the scan lines GLS and the output signal lines SLS. In the present embodiment, the scan line GLS includes a first scan line GLA and a second scan line GWG1. The first scan line GLA is provided so as to overlap the second scan line GWG1. The first and the second scan lines GLA and GWG1 are provided in different layers with insulating layers 22c and 22d (refer to FIG. 9) interposed therebetween. The first and the second scan lines GLA and GWG1 are electrically coupled together at any point, and are supplied with the gate drive signals VGL having the same potential. The first scan lines GLA, the second scan lines GWG1, or both are coupled to the scan line drive circuit 15. In FIG. 8, the first scan line GLA and the second scan line GWG1 have different widths, but may have the same width.

The photodiode 30 is provided in the area surrounded by the scan lines GLS and the output signal lines SLS. The photodiode 30 includes a semiconductor layer 31, an upper electrode 34, and a lower electrode 35. The photodiode 30 is a PIN photodiode, for example.

The upper electrode 34 is coupled to a power supply signal line Lvs through coupling wiring 36. The power supply signal line Lvs is wiring that supplies the power supply potential SVS to the photodiode 30. In the first embodiment, the power supply signal line Lvs extends in the second direction Dy while overlapping the output signal line SLS. The light-receiving elements 3 arranged in the second direction Dy are coupled to the same power supply signal line Lvs. Such a configuration can enlarge an opening for the light-receiving element 3. The lower electrode 35, the semiconductor layer 31, and the upper electrode 34 are substantially quadrilateral in plan view. However, the shapes of the lower electrode 35, the semiconductor layer 31, and the upper electrode 34 are not limited thereto and can be changed as appropriate.

The first transistor Tr is provided near an intersection between the scan line GLS and the output signal line SLS. The first transistor Tr includes a semiconductor layer 61, a source electrode 62, a drain electrode 63, a first gate electrode 64A, and a second gate electrode 64B.

The semiconductor layer 61 is an oxide semiconductor. The semiconductor layer 61 is more preferably a transparent amorphous oxide semiconductor (TAOS) among types of the oxide semiconductors. Using an oxide semiconductor as the first transistor TrS can reduce leakage currents of the first transistor Tr. That is, the first transistor Tr can reduce the leakage currents from the light-receiving element 3 that is not selected. Therefore, the detection device 1 can improve the signal-to-noise ratio (S/N). The semiconductor layer 61 is, however, not limited to this material and may be, for example, a microcrystalline oxide semiconductor, an amorphous oxide semiconductor, polysilicon, or low-temperature polycrystalline silicon (LTPS).

The semiconductor layer 61 is provided along the first direction Dx and intersects the first and the second gate electrodes 64A and 64B in plan view. The first and the second gate electrodes 64A and 64B are provided so as to branch from the first and the second scan lines GLA and same potential. The first scan lines GLA, the second scan lines GWG1, or both are coupled to the scan line drive circuit 15. In FIG. 8, the first scan line GLA and the second scan line GWG1 have different widths, but may have the same width.

One end of the semiconductor layer 61 is coupled to the source electrode 62 through a contact hole H1. The other end of the semiconductor layer 61 is coupled to the drain electrode 63 through a contact hole H2. A portion of the output signal line SLS that overlaps the semiconductor layer 61 serves as the source electrode 62. A portion of a third conductive layer 67 that overlaps the semiconductor layer 61 serves as the drain electrode 63. The third conductive layer 67 is coupled to the lower electrode 35 through a contact hole H3. Such a configuration allows the first transistor Tr to switch between coupling and decoupling between the photodiode 30 and the output signal line SLS.

The arrangement pitch of the light-receiving elements 3 (photodiodes 30) in the first direction Dx is defined by the arrangement pitch of the output signal lines SLS in the first direction Dx. The arrangement pitch of the light-receiving elements 3 (photodiodes 30) in the second direction Dy is defined by the arrangement pitch of the scan lines GLS in the second direction Dy.

The following describes a layer configuration of the optical sensor 5. FIG. 9 is a sectional view taken along IX-IX' in FIG. 8. In order to illustrate a relation between the layer structure of the detection area AA (refer to FIG. 5) and the layer structure of the peripheral area GA (refer to FIG. 5), FIG. 9 illustrates a section taken along a line IX-IX' and a section of a portion of the peripheral area GA that includes a second transistor TrG in a schematically connected manner. FIG. 9 further illustrates a section of a portion of the peripheral area GA that includes a terminal 72 in a schematically connected manner.

In the description of the optical sensor 5, a direction from the substrate 21 toward the photodiode 30 in a direction (third direction Dz) orthogonal to a surface of the substrate 21 is referred to as "upper side" or "above". A direction from the photodiode 30 toward the substrate 21 is referred to as "lower side" or "below". The term "plan view" refers to a positional relation as viewed along the direction orthogonal to the surface of the substrate 21.

As illustrated in FIG. 9, the substrate 21 is an insulating substrate, and is made using, for example, a glass substrate of quartz, alkali-free glass, or the like. The first transistors Tr, various types of wiring (the scan lines GLS and the output signal lines SLS), and insulating layers are provided to form the array substrate 2 on one surface of the substrate 21. The photodiodes 30 are arranged on the array substrate 2, that is, on the one surface side of the substrate 21. The substrate 21 may be a resin substrate or a resin film made of a resin such as polyimide.

Insulating layers 22a and 22b are provided on the substrate 21. Insulating layers 22a, 22b, 22c, 22d, 22e, 22f, and 22g are inorganic insulating films, and are formed of silicon oxide (SiO₂) or silicon nitride (SiN). Each of the inorganic insulating layers is not limited to a single layer and may be a multilayered film.

The first gate electrode 64A is provided on the insulating layer 22b. The insulating layer 22c is provided on the insulating layer 22b so as to cover the first gate electrode 64A. The semiconductor layer 61, a first conductive layer 65, and a second conductive layer 66 are provided on the insulating layer 22c. The first conductive layer 65 is provided so as to cover an end of the semiconductor layer 61 coupled to the source electrode 62. The second conductive layer 66 is provided so as to cover an end of the semiconductor layer 61 coupled to the drain electrode 63.

The insulating layer 22d is provided on the upper side of the insulating layer 22c so as to cover the semiconductor layer 61, the first conductive layer 65, and the second conductive layer 66. The second gate electrode 64B is provided on the insulating layer 22d. The semiconductor layer 61 is provided between the first gate electrode 64A and the second gate electrode 64B in the direction orthogonal to the substrate 21. That is, the first transistor Tr has what is called a dual-gate structure. The first transistor Tr may, however, have a bottom-gate structure that is provided with the first gate electrode 64A and not provided with the second gate electrode 64B, or a top-gate structure that is not provided with the first gate electrode 64A and provided with only the second gate electrode 64B.

The insulating layer 22e is provided on the upper side of the insulating layer 22d so as to cover the second gate electrode 64B. The source electrode 62 (output signal line SLS) and the drain electrode 63 (third conductive layer 67) are provided on the insulating layer 22e. In the first embodiment, the drain electrode 63 is the third conductive layer 67 provided above the semiconductor layer 61 with the insulating layers 22d and 22e interposed therebetween. The source electrode 62 is electrically coupled to the semiconductor layer 61 through the contact hole H1 and the first conductive layer 65. The drain electrode 63 is electrically coupled to the semiconductor layer 61 through the contact hole H2 and the second conductive layer 66.

The third conductive layer 67 is provided in an area overlapping the photodiode 30 in plan view. The third conductive layer 67 is provided also on the upper side of the semiconductor layer 61 and the first and the second gate electrodes 64A and 64B. That is, the third conductive layer 67 is provided between the second gate electrode 64B and the lower electrode 35 in the direction orthogonal to the substrate 21. This configuration causes the third conductive layer 67 to serve as a protective layer that protects the first transistor Tr.

The second conductive layer 66 extends so as to face the third conductive layer 67 in an area not overlapping the semiconductor layer 61. A fourth conductive layer 68 is provided on the insulating layer 22d in an area not overlapping the semiconductor layer 61. The fourth conductive layer 68 is provided between the second conductive layer 66 and the third conductive layer 67. This configuration generates capacitance between the second conductive layer 66 and the fourth conductive layer 68, and capacitance between the third conductive layer 67 and the fourth conductive layer 68. The capacitance generated by the second conductive layer 66, the third conductive layer 67, and the fourth conductive layer 68 serves as capacitance of the capacitive element Ca illustrated in FIG. 7.

A first organic insulating layer 23a is provided on the insulating layer 22e so as to cover the source electrode 62 (output signal line SLS) and the drain electrode 63 (third conductive layer 67). The first organic insulating layer 23a is a planarizing layer that planarizes asperities formed by the first transistor Tr and various conductive layers.

The following describes a sectional configuration of the photodiode 30. In the photodiode 30, the lower electrode 35, the semiconductor layer 31, and the upper electrode 34 are stacked in this order on the first organic insulating layer 23a of the array substrate 2. The array substrate 2 is a drive circuit board that drives the sensor for each predetermined detection area. The array substrate 2 includes the substrate 21, the first transistor Tr, the second transistor TrG, the various types of wiring, and so forth provided on the substrate 21.

The lower electrode 35 is provided on the first organic insulating layer 23a and is electrically coupled to the third conductive layer 67 through the contact hole H3. The lower electrode 35 is the anode of the photodiode 30 and is an electrode for reading the detection signal Vdet. For example, a metal material such as molybdenum (Mo) or aluminum (Al) is used as the lower electrode 35. The lower electrode 35 may alternatively be a multilayered film formed of a plurality of layers of these metal materials. The lower electrode 35 may be formed of a light-transmitting conductive material such as indium tin oxide (ITO) or indium zinc oxide (IZO).

The semiconductor layer 31 is formed of amorphous silicon (a-Si). The semiconductor layer 31 includes an i-type semiconductor layer 32a, an n-type semiconductor layer 32b, and a p-type semiconductor layer 32c. The i-type semiconductor layer 32a, the n-type semiconductor layer 32b, and the p-type semiconductor layer 32c form a specific example of a photoelectric conversion element. In FIG. 7, the p-type semiconductor layer 32c, the i-type semiconductor layer 32a, and the n-type semiconductor layer 32b are stacked in this order in the direction orthogonal to the surface of the substrate 21. However, the semiconductor layer 31 may have a reversed configuration. That is, the n-type semiconductor layer 32b, the i-type semiconductor layer 32a, and the p-type semiconductor layer 32c may be stacked in this order. The semiconductor layer 31 may be a photoelectric conversion element formed of organic semiconductors.

The a-Si of the n-type semiconductor layer 32b is doped with impurities to form an n+ region. The a-Si of the p-type semiconductor layer 32c is doped with impurities to form a p+ region. The i-type semiconductor layer 32a is, for example, a non-doped intrinsic semiconductor, and has lower conductivity than that of the n-type semiconductor layer 32b and the p-type semiconductor layer 32c.

The upper electrode 34 is the cathode of the photodiode 30, and is an electrode for supplying the power supply potential SVS to the photoelectric conversion layers. The upper electrode 34 is, for example, a light-transmitting conductive layer of, for example, ITO, and a plurality of the upper electrodes 34 are provided for the respective photodiodes 30.

The insulating layers 22f and 22g are provided on the first organic insulating layer 23a. The insulating layer 22f covers the periphery of the upper electrode 34 and is provided with an opening in a position overlapping the upper electrode 34. The coupling wiring 36 is coupled to the upper electrode 34 at a portion of the upper electrode 34 not provided with the insulating layer 22f. The insulating layer 22g is provided on the insulating layer 22f so as to cover the upper electrode 34 and the coupling wiring 36. A second organic insulating layer 23b serving as a planarizing layer is provided on the insulating layer 22g. In the case of the organic semiconductor photodiode, an insulating layer 22h may be further provided thereon.

The second transistor TrG of the scan line drive circuit 15 is provided in the peripheral area GA. The second transistor TrG is provided on the substrate 21 on which the first transistor Tr is provided. The second transistor TrG includes a semiconductor layer 81, a source electrode 82, a drain electrode 83, and a gate electrode 84.

The semiconductor layer 81 is polysilicon. The semiconductor layer 81 is more preferably low-temperature polysilicon (LTPS). The semiconductor layer 81 is provided on the insulating layer 22a. That is, the semiconductor layer 61 of the first transistor Tr is provided in a position farther from the substrate 21 than the semiconductor layer 81 of the second transistor TrG is, in the direction orthogonal to the substrate 21. However, the semiconductor layer 81 is not limited to this configuration and may be formed in the same layer and of the same material as the semiconductor layer 61.

The gate electrode 84 is provided on the upper side of the semiconductor layer 81 with the insulating layer 22b interposed therebetween. The gate electrode 84 is provided in the same layer as the first gate electrode 64A. The second transistor TrG has what is called a top-gate structure. The second transistor TrG may, however, have a dual-gate structure or a bottom-gate structure.

The source electrode 82 and the drain electrode 83 are provided on the insulating layer 22e. The source electrode 82 and the drain electrode 83 are provided in the same layer as the source electrode 62 and the drain electrode 63 of the first transistor Tr. Contact holes H4 and H5 are provided penetrating from the insulating layer 22b to the insulating layer 22e. The source electrode 82 is electrically coupled to the semiconductor layer 81 through the contact hole H4. The drain electrode 83 is electrically coupled to the semiconductor layer 81 through the contact hole H5.

The terminal 72 is provided in a position of the peripheral area GA different from the area where the scan line drive circuit 15 is provided. The terminal 72 includes a first terminal conductive layer 73, a second terminal conductive layer 74, a third terminal conductive layer 75, and a fourth terminal conductive layer 76. The first terminal conductive layer 73 is provided in the same layer as the first gate electrode 64A on the insulating layer 22b. A contact hole H6 is provided so as to penetrate the insulating layers 22c, 22d, 22e and the first organic insulating layer 23a.

The second terminal conductive layer 74, the third terminal conductive layer 75, and the fourth terminal conductive layer 76 are stacked in this order in the contact hole H6 and are electrically coupled to the first terminal conductive layer 73. The second terminal conductive layer 74 can be formed using the same material and the same process as those of the third conductive layer 67, for example. The third terminal conductive layer 75 can be formed using the same material and the same process as those of the lower electrode 35. The fourth terminal conductive layer 76 can be formed using the same material and the same process as those of the coupling wiring 36 and the power supply signal line Lvs (refer to FIG. 8).

While FIG. 9 illustrates one terminal 72, a plurality of the terminals 72 are arranged at intervals. The terminals 72 are electrically coupled to the wiring substrate 510 (refer to FIG. 5), for example, by anisotropic conductive films (ACFs) or the like.

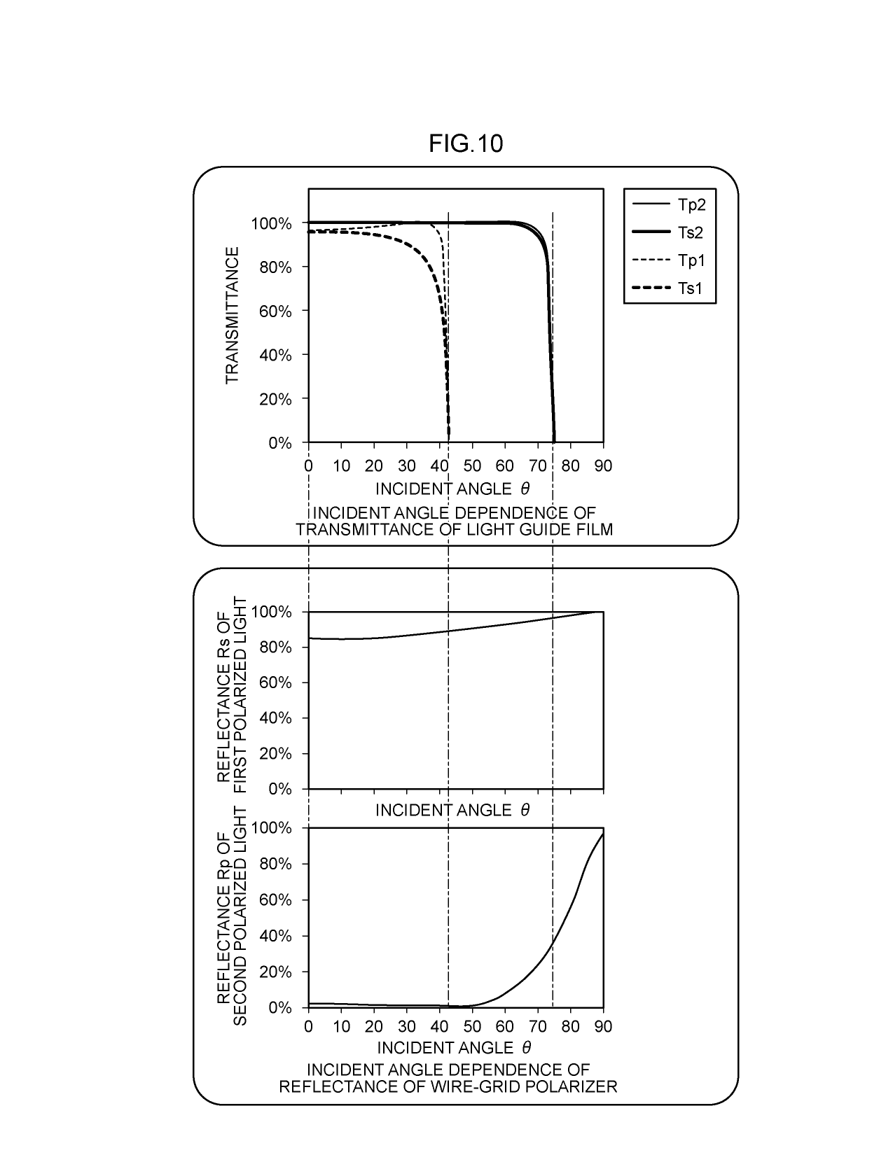

FIG. 10 depicts explanatory diagrams illustrating a relation between incident dependence of the transmittance of the light guide film and incident dependence of reflectance of the wire-grid polarizer in the first embodiment.

As illustrated in FIGS. 2 and 10, when an incident angle θ at which the light L is incident on the light guide film LG is within a range of 0° < θ < 43°, the light L is incident on an epidermal interface of the object to be detected FG through the light guide film LG and an air interface, or directly. In this case, the first polarized light L1 is transmitted through the light guide film LG at transmittance Ts1 of 80% or more, and the second polarized light L2 is transmitted through the light guide film LG at transmittance Tp1 of substantially 100%. The transmittance Ts1 is a ratio at which the first polarized light L1 is transmitted through the light guide film LG. The transmittance Tp1 is a ratio at which the second polarized light L2 is transmitted through the light guide film LG.

In this case, the wire-grid polarizer WG1 reflects the first polarized light L1 at reflectance Rs of 80% or more and does not reflect the second polarized light L2. The light emitted as the first polarized light L1 is transmitted through or reflected on the epidermal surface of the object to be detected FG. At this time, the first polarized light L1 reflected from the epidermal surface of the object to be detected FG is not detected by the optical sensor 5 because the first polarized light L1 is not transmitted through the wire-grid polarizer WG1.

As illustrated in FIGS. 2 and 10, when the incident angle θ is within a range of 43° < θ < 75°, the light L is totally reflected between the light guide film LG and the air interface, but when the light guide film LG is in contact with the object to be detected FG, the light is incident on the epidermal surface within the incident angle θ of 0° ≤ θ < 75° and the first and the second polarized light L1 and L2 are transmitted from the light guide film LG into the object to be detected FG at transmittance Tp2 and Ts2, respectively, of substantially 100%. The transmittance Ts2 is a ratio at which the first polarized light L1 is transmitted from the light guide film LG into the object to be detected FG. The transmittance Tp2 is a ratio at which the second polarized light L2 is transmitted from the light guide film LG into the object to be detected FG.

In this case, when the incident angle θ is within a range of 43° < θ < 75°, the wire-grid polarizer WG1 reflects the first polarized light L1 at reflectance Rs of 90% or more. The reflectance Rp of the second polarized light L2 increases with increase of the incident angle θ, and thus the second polarized light L2 is reflected at the reflectance Rp of 3% to 40%. Part of the light reflected by the wire-grid polarizer WG1 contains the second polarized light L2, and part of the light reflected from the epidermal interface of the object to be detected FG also contains the second polarized light L2. The second polarized light L2 reflected from the epidermal interface of the object to be detected FG is transmitted through the wire-grid polarizer WG1, but cannot be detected by the light-receiving element 3 because the magnitude of the acceptance angle of the optical filter layer 50 is larger than approximately 20°.

Therefore, the first polarized light L1 from the surface of the object to be detected FG that is a cause of noise can be significantly reduced, and light signals detected by the light-receiving element 3 are mainly formed by the second polarized light L2 of the backscattered light in the dermis region, thus enabling imaging of subcutaneous blood vessels and the like at a high signal-to-noise ratio (SNR).

### Second Embodiment

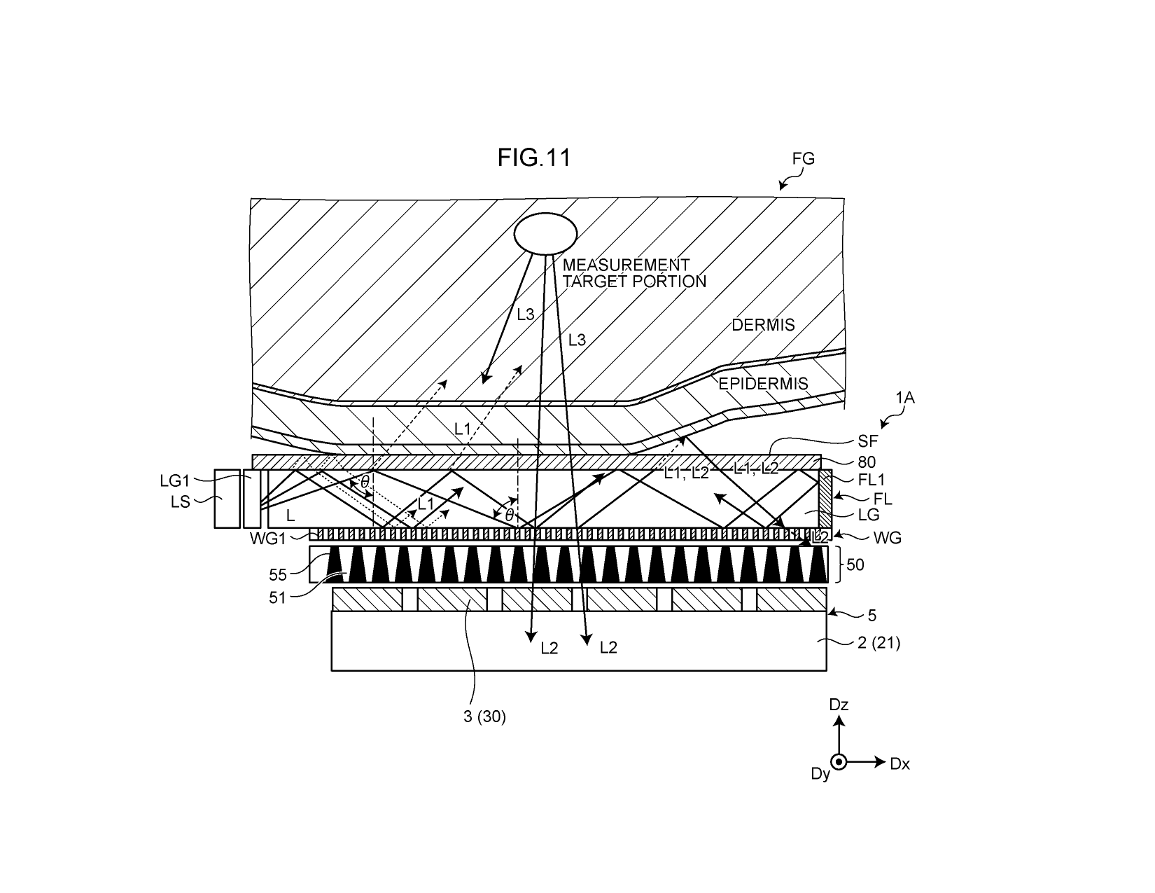

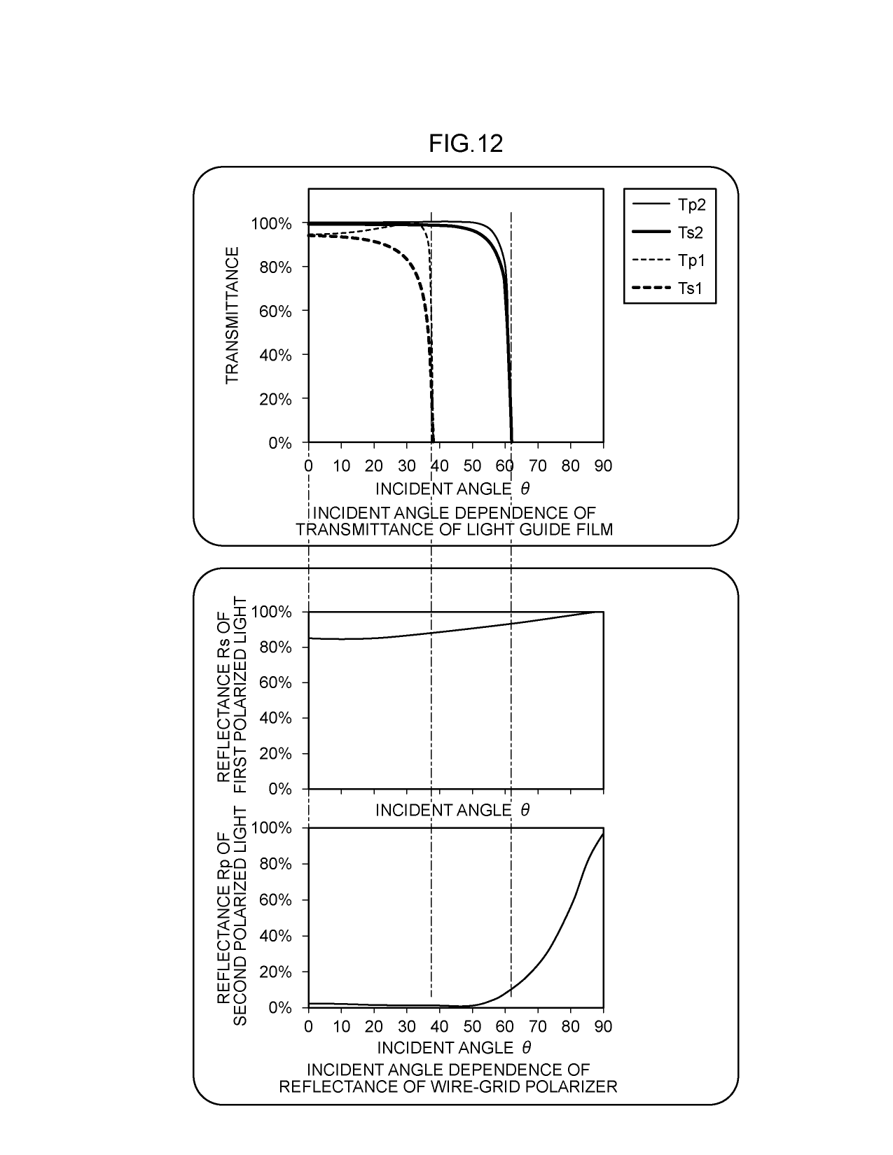

FIG. 11 is a sectional view schematically illustrating a section of a detection device according to a second embodiment of the present disclosure. FIG. 12 depicts explanatory diagrams illustrating the relation between the incident dependence of the transmittance of the light guide film and the incident dependence of the reflectance of the wire-grid polarizer in the second embodiment. In the following description, the same components as those described in the embodiment described above are denoted by the same reference numerals, and the description thereof will not be repeated.

As illustrated in FIG. 11, in a detection device 1A according to the second embodiment, a light-transmitting protective film 80 is located on the detection surface SF on the object to be detected FG side of the light guide film LG.

A light-transmitting film excellent in thermal resistance and durability is used as the protective film 80. The protective film 80 is, for example, silicone rubber, polyurethane, or polyethylene terephthalate (PET). This configuration can reduce skin irritation of the object to be detected FG.

The refractive index of the protective film 80 is higher than that of the light guide film LG (1.487). The refractive index of the protective film 80 is also higher than that of the epidermis of the object to be detected FG (1.43). The refractive index of the protective film 80 is, for example, 1.63.

As illustrated in FIG. 12, the incident angle θ of incidence on the epidermal surface of the object to be detected FG is reduced from 75° to 62°. In this case, when the light L travels from the light guide film LG toward the protective film 80, the light L travels from a medium having a lower refractive index to a medium having a higher refractive index. Therefore, the light L can more easily enter the skin by an extent of the reduction of the incident angle θ. As a result, surface reflection components (first polarized light L1) from the skin surface that are a cause of noise can be reduced.

When the light L travels from the protective film 80 toward the epidermis of the object to be detected FG, the light L travels from a medium having a higher refractive index to a medium having a lower refractive index. Therefore, when the incident angle θ is larger than the critical angle, the light L is totally reflected on the surface of the protective film 80, and the ratio of the light guided to the entire surface of the optical sensor 5 increases.

When the light guide film LG is used by being wound around a wrist or the like and becomes curved, the incident angle θ of light on the inner diameter side of the light guide film LG effectively increases. Therefore, the total reflection at the air interface is facilitated, the angle range of light irradiation to the epidermis becomes narrow, which can reduce the surface reflection components from the skin surface that are a cause of noise.

### Third Embodiment

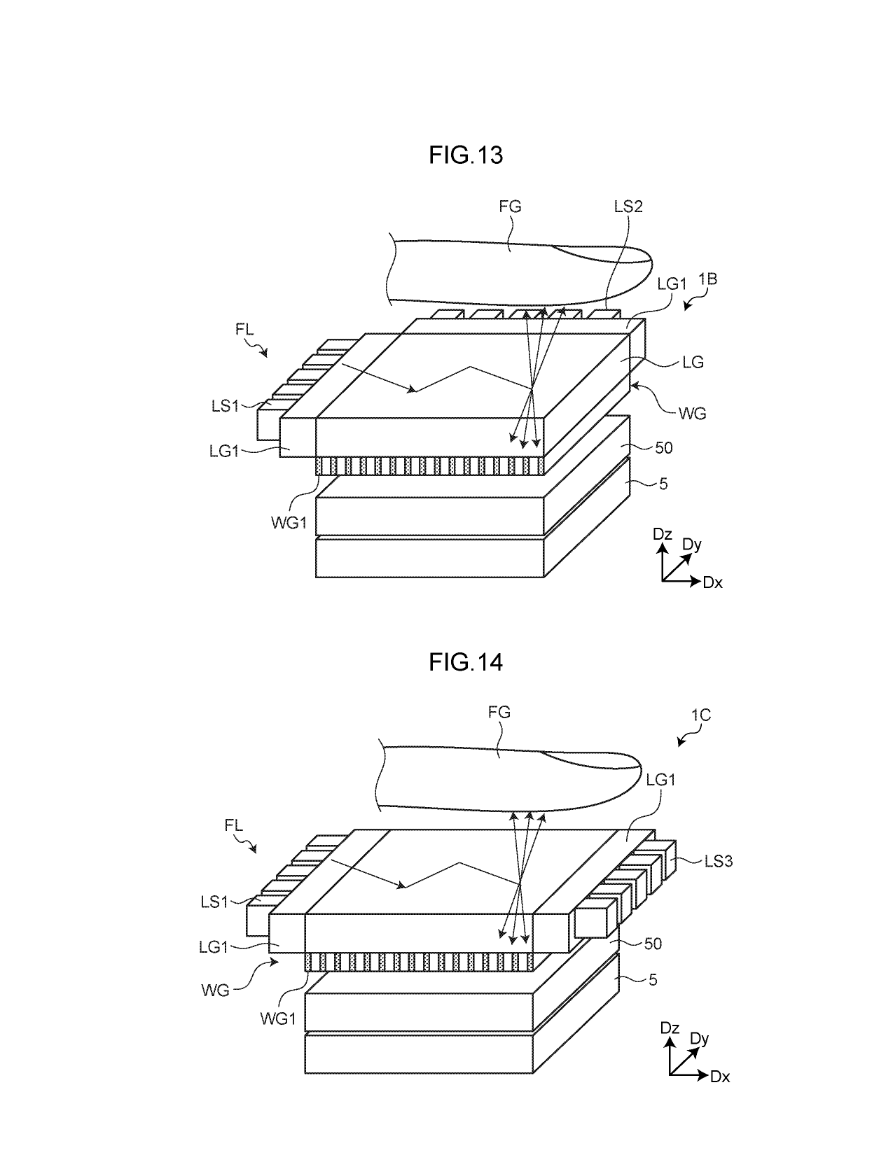

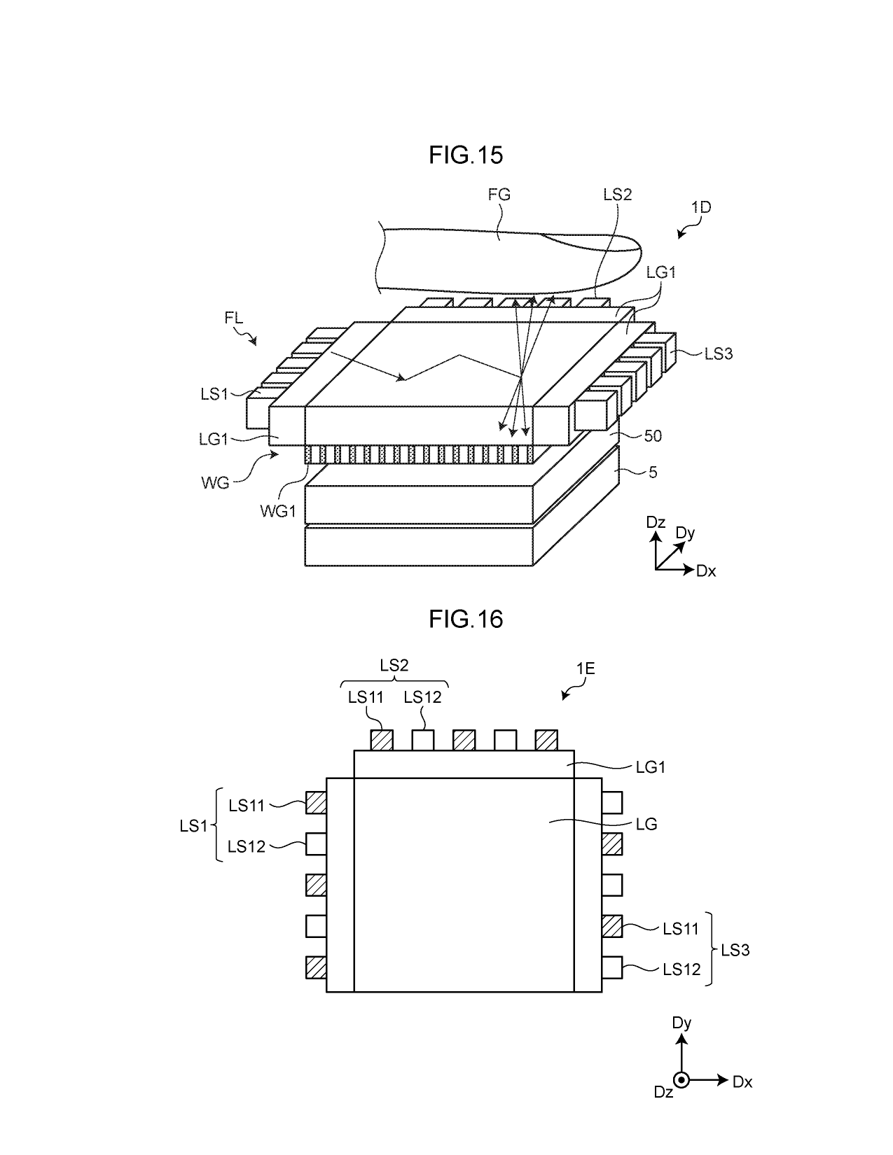

FIG. 13 is a perspective view schematically illustrating an example of a detection device according to a third embodiment of the present disclosure. FIG. 14 is a perspective view schematically illustrating a different example from the detection device of FIG. 13. FIG. 15 is a perspective view schematically illustrating a different example from the detection device of FIG. 13. In the following description, the same components as those described in either of the embodiments described above are denoted by the same reference numerals, and the description thereof will not be repeated.

A plurality of light sources LS1, LS2, and LS3 are arranged on two orthogonal sides, two opposed sides, or three sides of the light guide film LG. Specifically, as illustrated in FIG. 13, in a detection device 1B according to the third embodiment, the multiple light sources LS1 are provided at the first side surface of the light guide film LG, and the multiple light sources LS2 are provided at a second side surface of the light guide film LG that is orthogonal to the first side surface and not provided with the wiring substrate 510.

The polarization component that is reflected or transmitted is determined by the wire direction of the wire-grid polarizer WG1 regardless of the incident direction of the light L. The first polarized light L1 oscillating in parallel along the wire direction of the wire-grid polarizer WG1 is reflected by the wire-grid polarizer WG1, and the second polarized light L2 oscillating orthogonal to the wire direction of the wire-grid polarizer WG1 is transmitted through the wire-grid polarizer WG1. As illustrated in FIG. 4A, when the light incident from the light sources LS1 is orthogonal to the wire-grid polarizer WG1 (orthogonal to the second direction Dy), the first polarized light L1 oscillating in parallel along the wire direction is reflected by the wire-grid polarizer WG1, and the second polarized light L2 oscillating orthogonally to the wire direction is transmitted through the wire-grid polarizer WG1. In contrast, as illustrated in FIG. 4B, when the light incident from the light sources LS2 provided orthogonally to the light sources LS1 is parallel to the wire-grid polarizer WG1 (parallel to the second direction Dy), the first polarized light L1 oscillating in parallel along the wire direction is reflected by the wire-grid polarizer WG1, and the second polarized light L2 oscillating orthogonally to the wire direction is transmitted through the wire-grid polarizer WG1. Therefore, the polarization components reflected or transmitted by the wire-grid WG1 for the light sources LS1 and LS2 that have different incident directions and are arranged orthogonally to each other exhibit the same polarization direction.

As illustrated in FIG. 14, in a detection device 1C, the multiple light sources LS1 are provided at the first side surface of the light guide film LG, and the multiple light sources LS3 are provided at a third side surface opposite the first side surface of the light guide film LG. In the case of light incident from the light sources LS3, in the same way as the case of the light incident from the light sources LS1, the first polarized light L1 is reflected by the wire-grid polarizer WG1 and the second polarized light L2 is transmitted through the wire-grid polarizer WG1.

As illustrated in FIG. 15, in a detection device 1D, the light sources LS1 are provided at the first side surface of the light guide film LG, and the light sources LS2 are provided at the second side surface of the light guide film LG that is orthogonal to the first side surface and is not provided with the wiring substrate 510. The light sources LS3 are provided at the third side surface opposite the first side surface of the light guide film LG. The light sources LS2 are not provided at the side surface provided with the wiring substrate 510.

Since this configuration increases the amount of light propagating in the light guide film LG, the amount of reflected light reflected by the measurement target portion of the object to be detected FG increases, thus improving the efficiency of guiding the light incident on the optical sensor 5.

### Fourth Embodiment

FIG. 16 is a plan view schematically illustrating a detection device according to a fourth embodiment of the present disclosure. In the following description, the same components as those described in any one of the embodiments described above are denoted by the same reference numerals, and the description thereof will not be repeated.

As illustrated in FIG. 16, in a detection device 1E, the light sources LS1, LS2, and LS3 include first light sources LS11 and second light sources LS12. The first light sources LS11 and the second light sources LS12 are alternately arranged. The first light sources LS11 and the second light sources L12 each emit at least one of red light, green light, infrared light, near-infrared light, and visible light. The wavelength of the light of the first light sources L11 differs from that of the light of the second light sources L12.

For example, the first light sources LS11 emit near-infrared light or infrared light. The second light sources LS12 emit green or red light. The green light has a wavelength of 490 nm to 550 nm, for example. The red light has a wavelength of 640 nm to 770 nm, for example. The infrared light has a wavelength of approximately 2500 nm to approximately 25 μm, for example. The near-infrared light has a wavelength of approximately 770 nm to approximately 2500 nm, for example. In the present embodiment, the light sources having two types of different wavelengths are arranged, but three or more types of different light sources may be alternately arranged.

This configuration improves the efficiency of light guide because the two types of different wavelengths enter the optical sensor 5 more uniformly.

### Fifth Embodiment

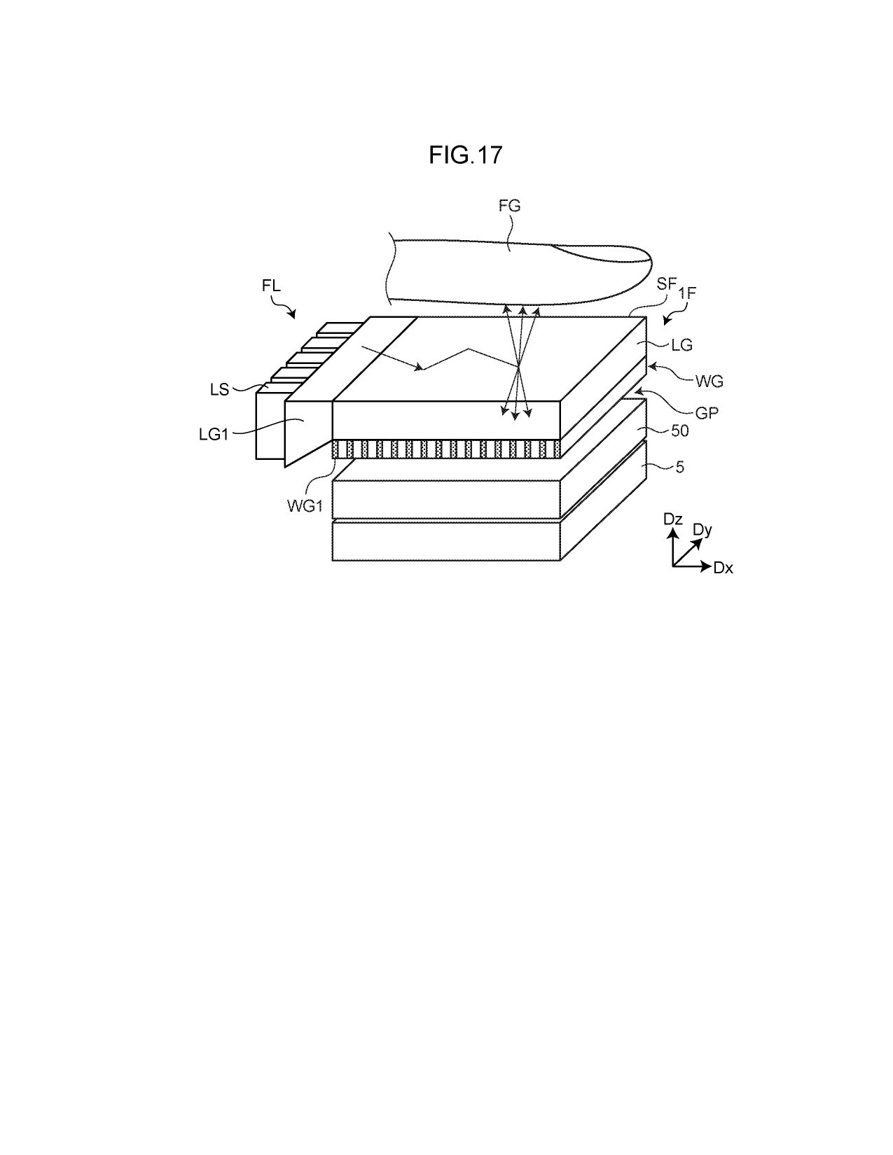

FIG. 17 is a perspective view schematically illustrating a detection device according to a fifth embodiment of the present disclosure. In the following description, the same components as those described in any one of the embodiments described above are denoted by the same reference numerals, and the description thereof will not be repeated.

As illustrated in FIG. 17, in a detection device 1F according to the fifth embodiment, the shape of the light entrance LG1 provided on a side surface side of the light guide film LG on which the light L of the light guide film LG is incident is trapezoidal in sectional view in a plane orthogonal to the second direction Dy (Dx-Dz plane).

The light entrance LG1 has two parallel sides. The shorter one of the two sides faces the light guide film LG. The longer one of the two sides faces the light source LS. Therefore, the thickness of the light entrance LG1 facing the light source LS is larger than the thickness of the light guide film LG.

This configuration ensures emission of the light from the light source LS into the light guide film LG and reduction of the amount of light leakage.

### Sixth Embodiment

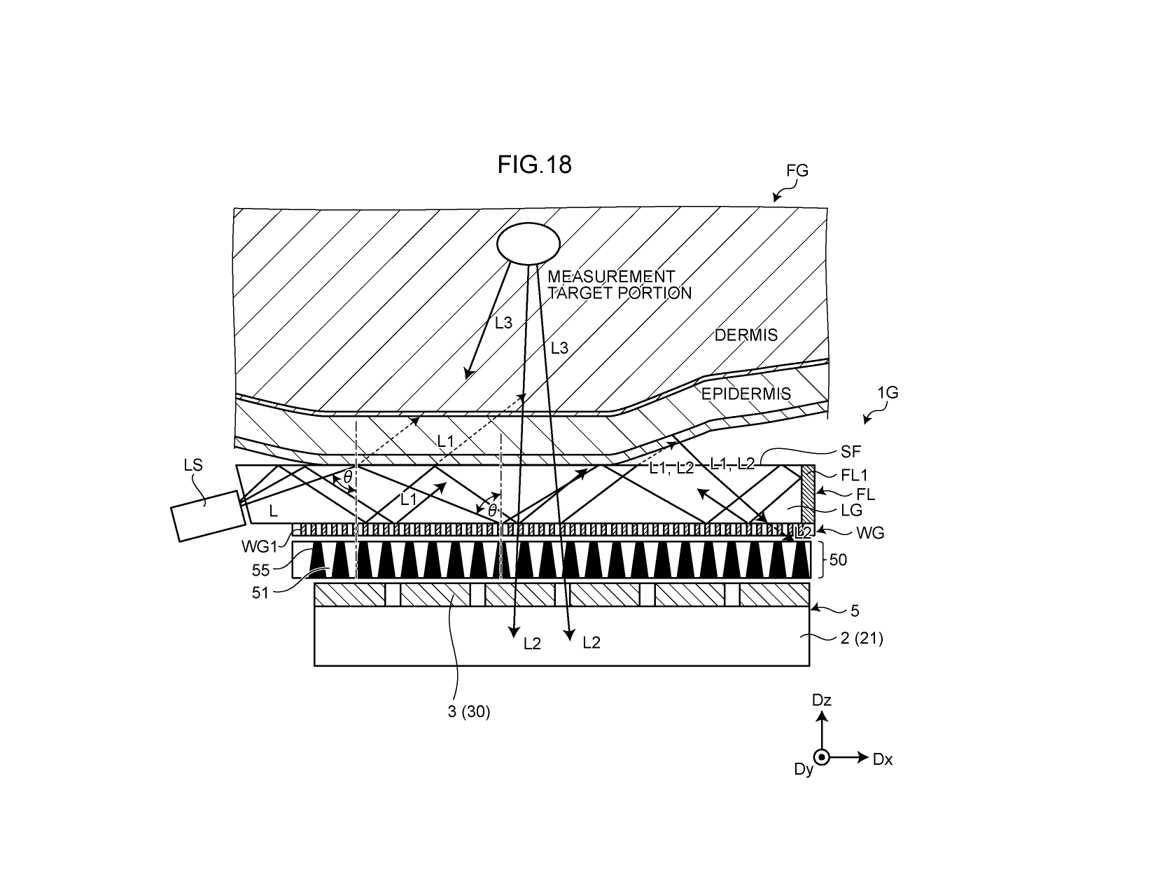

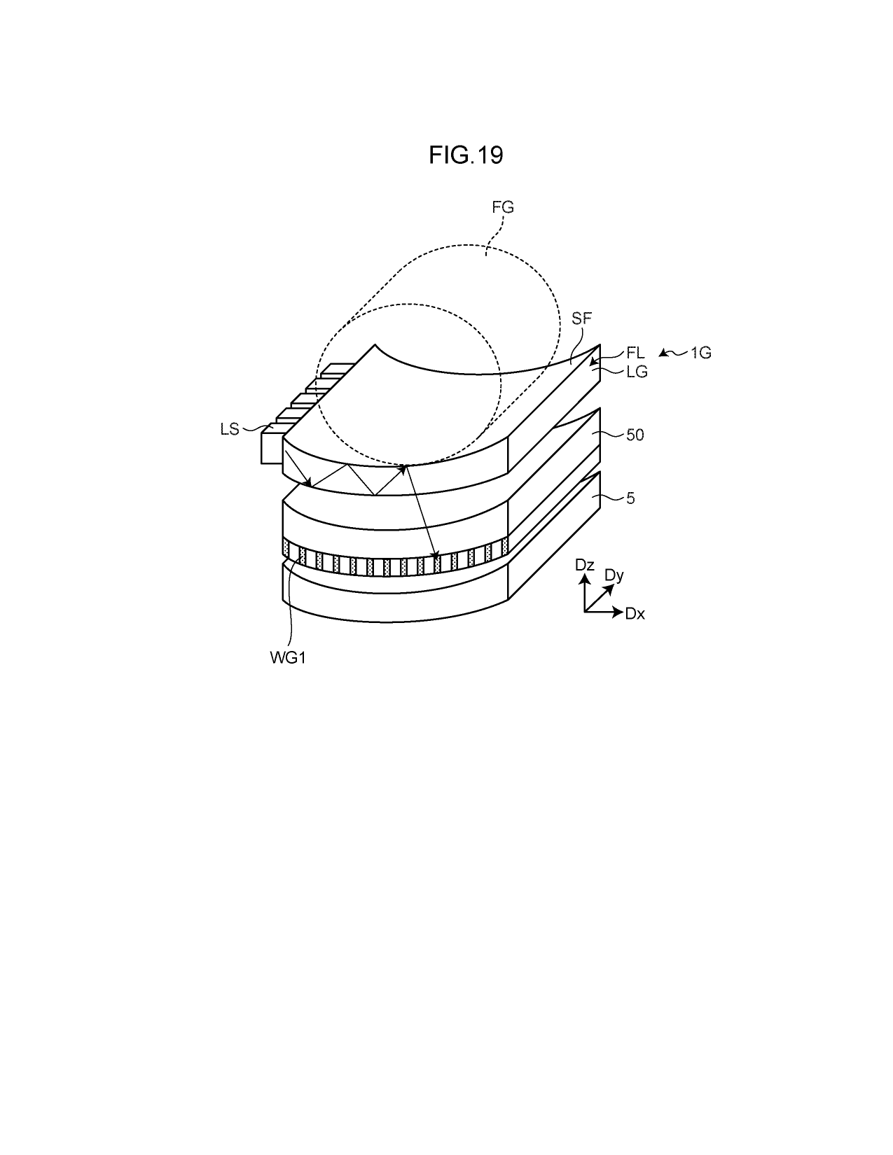

FIG. 18 is a sectional view schematically illustrating a section of a detection device according to a sixth embodiment of the present disclosure. FIG. 19 is a perspective view schematically illustrating the detection device according to the sixth embodiment. In the following description, the same components as those described in any one of the embodiments described above are denoted by the same reference numerals, and the description thereof will not be repeated.

As illustrated in FIG. 18, in a detection device 1G according to the sixth embodiment, a side surface of the light guide film LG is inclined with respect to the normal direction of the detection surface SF of the light guide film LG facing the object to be detected FG, and the light source LS faces the inclined side surface of the light guide film LG.

This configuration can reduce the loss of the light incident from the light source LS and can improve the efficiency of light guide to the light guide film LG. The light emission intensity of the light source LS can be increased, and power consumption can be reduced.

As illustrated in FIG. 19, the light guide film LG is curved in the detection device 1G according to the sixth embodiment. The array substrate 2 (substrate 21) is a flexible substrate that is made of a resin and flexible or pliable. The flexible array substrate 2 (substrate 21) is curved along the curvature of the light guide film LG.

### Seventh Embodiment

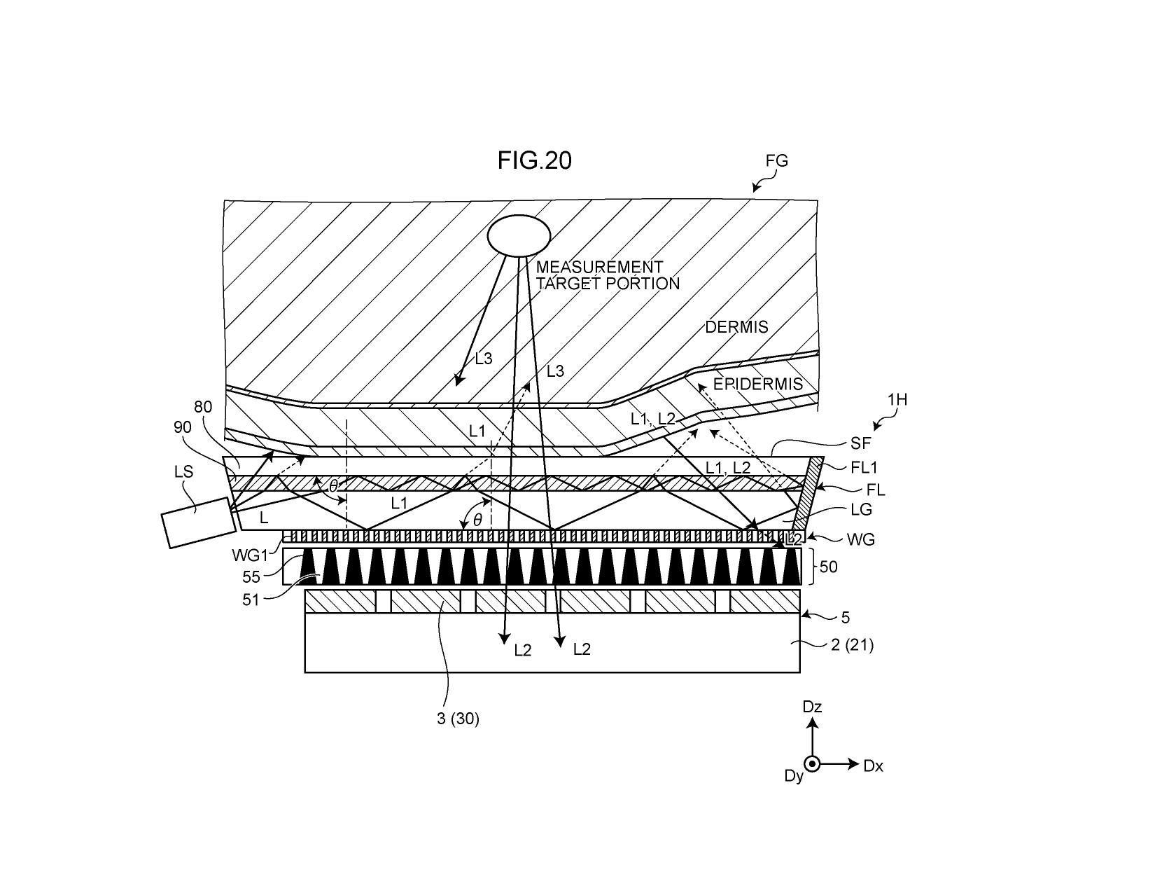

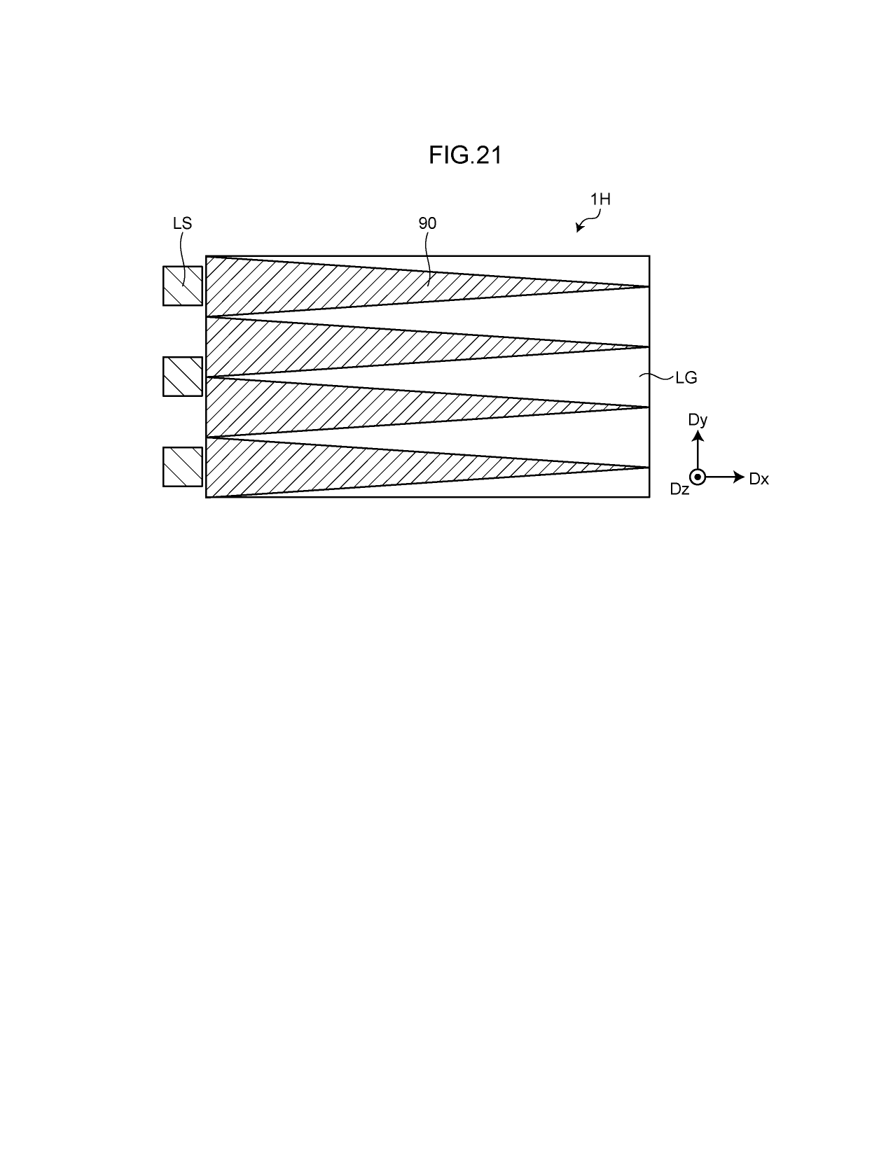

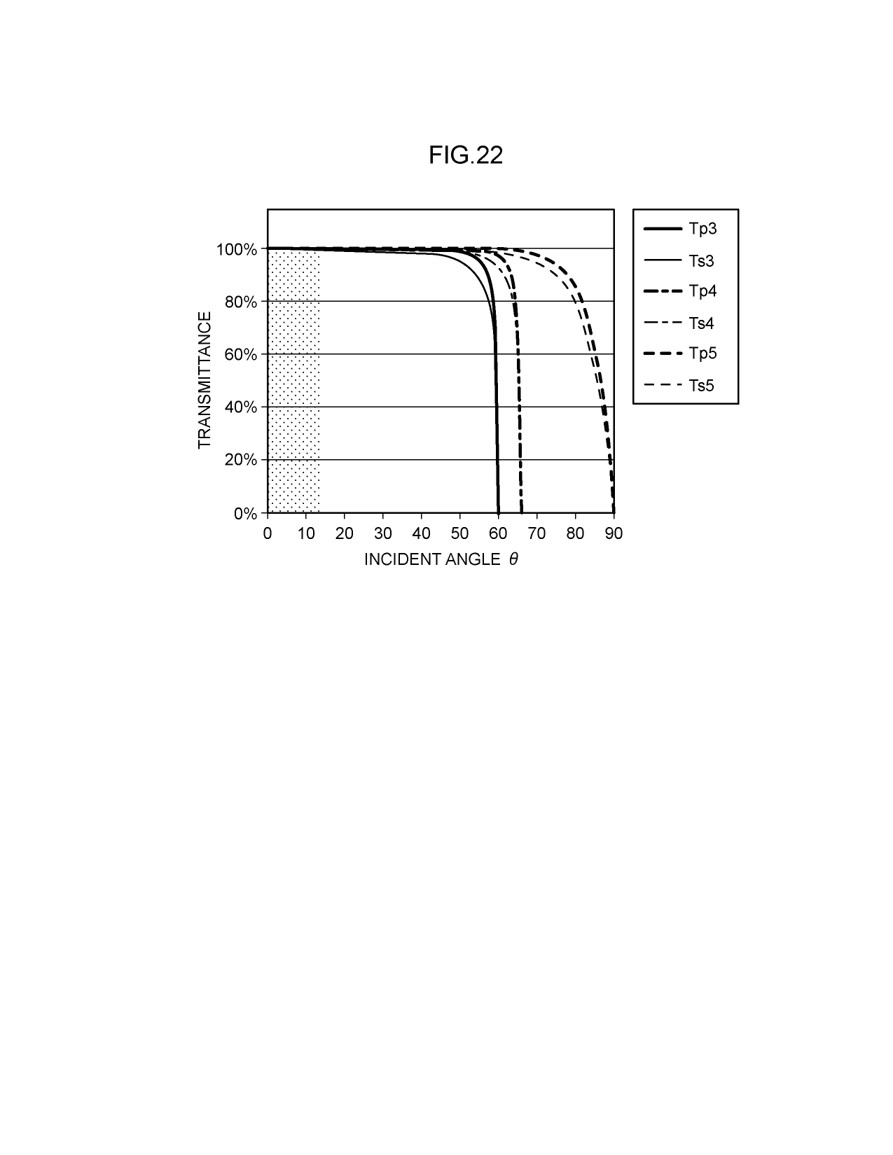

FIG. 20 is a sectional view schematically illustrating a section of a detection device according to a seventh embodiment of the present disclosure. FIG. 21 is a plan view schematically illustrating the detection device according to the seventh embodiment. FIG. 22 is an explanatory diagram illustrating the transmittance of a high refractive index waveguide layer versus the incident angle thereon in the seventh embodiment. In the following description, the same components as those described in any one of the embodiments described above are denoted by the same reference numerals, and the description thereof will not be repeated.

As illustrated in FIG. 20, in a detection device 1H according to the seventh embodiment, the detection surface SF of the light guide film LG facing the object to be detected FG is provided with the protective film 80 and a high refractive index waveguide layer 90. The high refractive index waveguide layer 90 is located between the protective film 80 and the light guide film LG.

The protective film 80 is, for example, polydimethylsiloxane (PDMS) that has a low refractive index.

A film having a high refractive index is used as the high refractive index waveguide layer 90. The high refractive index waveguide layer 90 is formed of, for example, polyacrylate with dispersed zirconia nanoparticles or titanium oxide nanoparticles. The refractive index of the high refractive index waveguide layer 90 is from 1.65 to 1.71, which is higher than the refractive index (1.487) of the light guide film LG, and higher than the refractive index (1.41) of the protective film 80.

As illustrated in FIG. 21, the high refractive index waveguide layer 90 is triangular in plan view. This configuration changes the incident angle of the light L guided from the light guide film LG to the high refractive index waveguide layer 90 that differ in refractive index. Therefore, the light L slightly leaks from two sides of the triangular shape and thereby can be guided uniformly in plane. The number of the light sources need not match the number of high refractive index waveguide layers. The two sides of the triangular shape of the high refractive index waveguide layer 90 may be formed by curves instead of straight lines.

FIG. 22 is the explanatory diagram illustrating the transmittance of the high refractive index waveguide layer versus the incident angle thereon in the seventh embodiment.

As illustrated in FIGS. 20 and 22, when the incident angle θ at which the light L is incident on the light guide film LG is within a range of 0° < θ < 60°, the light L that has entered the high refractive index waveguide layer 90 is refracted by the protective film 80 and transmitted to the epidermis. In this case, the first polarized light L1 and the second polarized light L2 are transmitted from the high refractive index waveguide layer 90 into the object to be detected FG at transmittance Tp3 and Ts3, respectively, of substantially 100%. The transmittance Ts3 is a ratio of the first polarized light L1 transmitted from the high refractive index waveguide layer 90 to the protective film 80. The transmittance Tp3 is a ratio of the second polarized light L2 transmitted from the high refractive index waveguide layer 90 to the protective film 80.

As illustrated in FIGS. 20 and 22, when the incident angle θ is within a range of 60° < θ < 65°, the light L that has entered the high refractive index waveguide layer 90 is refracted by the light guide film LG and emitted to the wire-grid polarizer WG1. In this case, the first polarized light L1 and the second polarized light L2 enter the light guide film LG from the high refractive index waveguide layer 90 at transmittance Tp4 and Ts4, respectively, of substantially 100%. The transmittance Ts4 is a ratio of the first polarized light L1 transmitted through the high refractive index waveguide layer 90. The transmittance Tp4 is a ratio of the second polarized light L2 transmitted through the high refractive index waveguide layer 90.

As illustrated in FIGS. 20 and 22, when the incident angle θ is within a range of 65° < θ < 90°, the light L that has entered the high refractive index waveguide layer 90 propagates within the high refractive index waveguide layer 90 and is guided toward the reflector plate FL1. In this case, the first polarized light L1 and the second polarized light L2 are transmitted from the light guide film LG into the high refractive index waveguide layer 90 at transmittance Tp5 and Ts5, respectively. The transmittance Ts5 is a ratio of the first polarized light L1 that is transmitted from the light guide film LG into the high refractive index waveguide layer 90. The transmittance Tp5 is a ratio of the second polarized light L2 that is transmitted from the light guide film LG into the high refractive index waveguide layer 90.

Thus, the light can be uniformly emitted to the entire surface of the optical sensor 5 provided with the light-receiving elements 3, and the detection accuracy can be improved.

The front light FL includes the reflector plate FL1 at a side surface of the light guide film LG opposite the side surface facing the light source LS. The side surface of the reflector plate FL1 is inclined at an angle equal to or larger than the acceptance angle that is the maximum angle at which the light L enters the optical filter layer 50.

This configuration allows the light incident on the reflector plate FL1 to be reflected toward the epidermis through the high refractive index waveguide layer 90 or the protective film 80, thereby effectively using the light guided through the high refractive index waveguide layer 90 and the light guide film LG, and also improving the power efficiency of the detection device.

### Eighth Embodiment

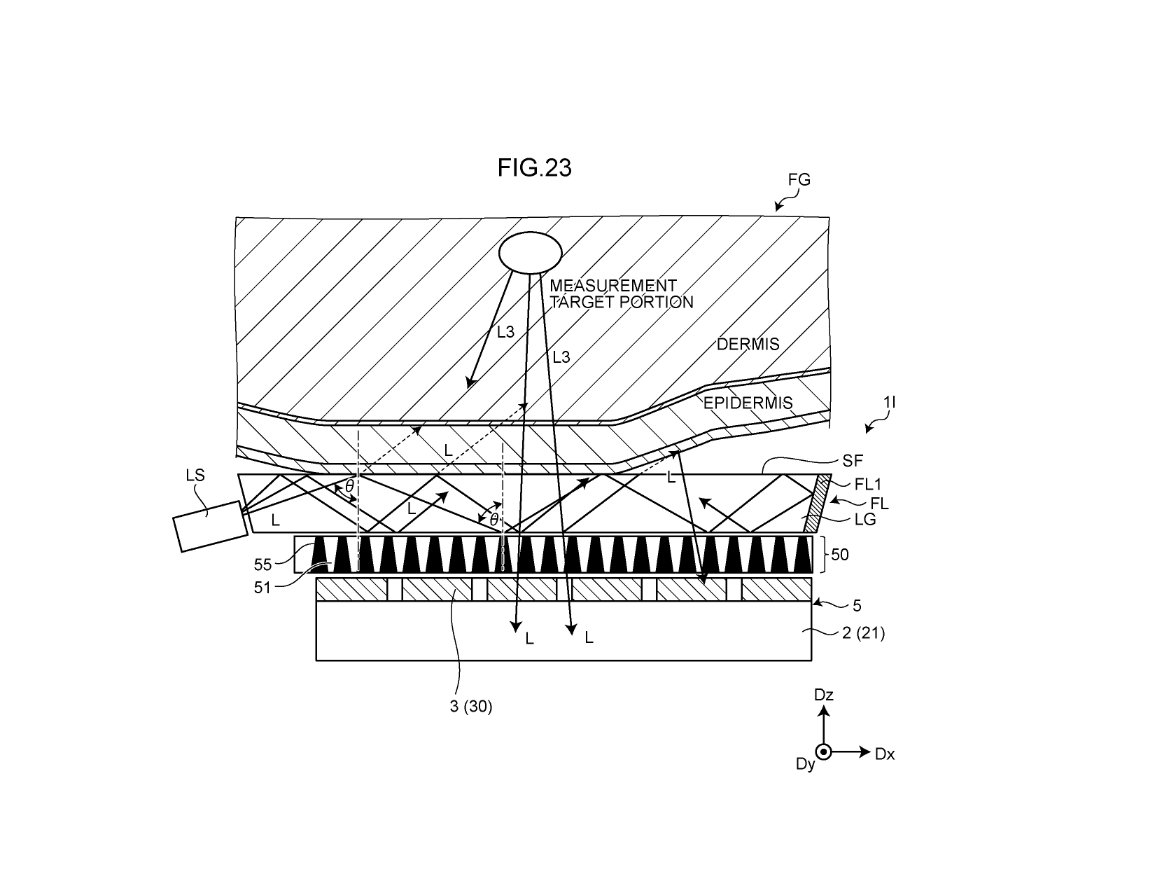

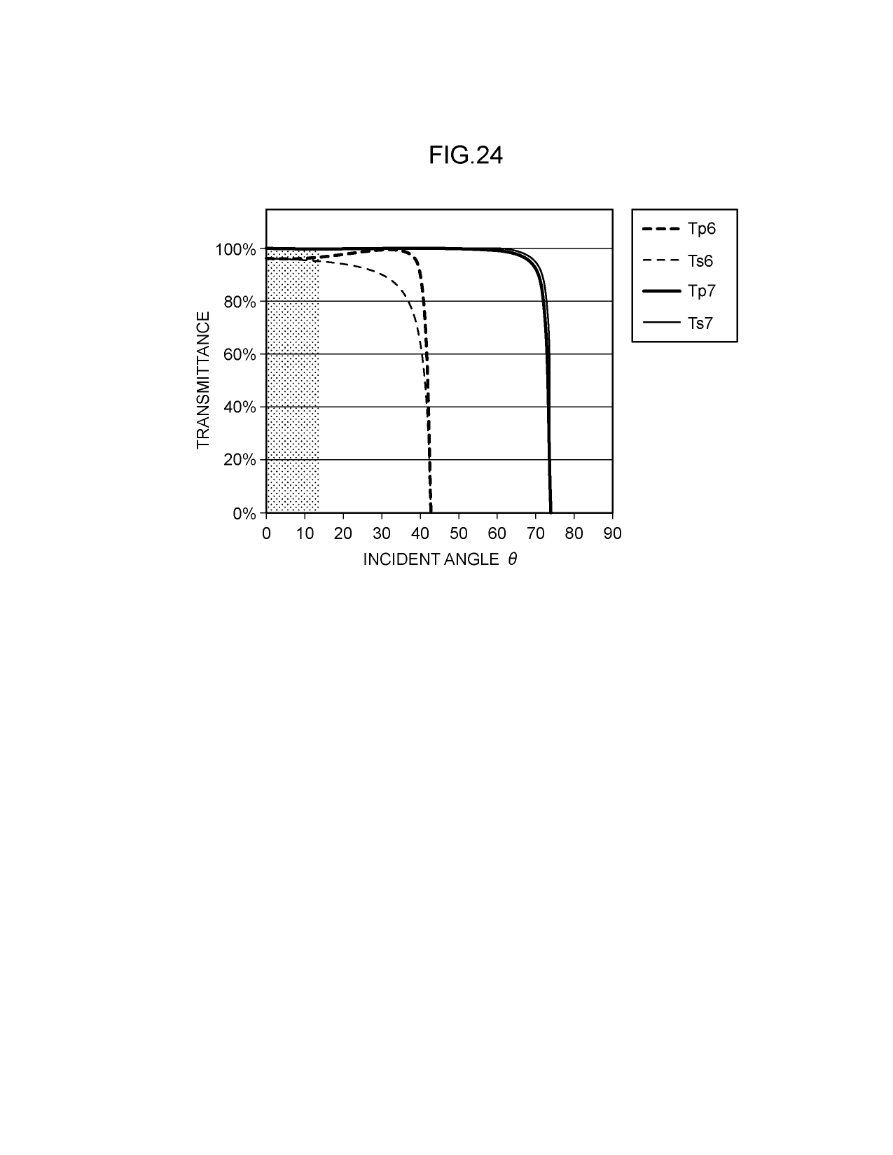

FIG. 23 is a sectional view schematically illustrating a section of a detection device according to an eighth embodiment of the present disclosure. FIG. 24 is an explanatory diagram illustrating the transmittance of the light guide film versus the incident angle thereon in the eighth embodiment. In the following description, the same components as those described in any one of the embodiments described above are denoted by the same reference numerals, and the description thereof will not be repeated.

As illustrated in FIG. 23, a detection device 1I according to the eighth embodiment includes the optical sensor 5, the front light FL, and the optical filter layer 50. The optical sensor 5, the optical filter layer 50, and the front light FL are stacked in this order on the substrate 21.

As illustrated in FIGS. 23 and 24, when the incident angle θ at which the light L is incident on the light guide film LG is within a range of 0° < θ < 43°, the first polarized light L1 is transmitted through the optical filter layer 50 at the transmittance Ts6 of 80% or more, and the second polarized light L2 is transmitted through the optical filter layer 50 at the transmittance Tp6 of substantially 100%. Transmittance Ts6 is a ratio of the first polarized light L1 transmitted through the optical filter layer 50. Transmittance Tp6 is a ratio of the second polarized light L2 transmitted through the optical filter layer 50.

In this case, when the light is emitted to the epidermis through the air interface or directly, and the magnitude of the acceptance angle of the optical filter layer 50 is within approximately 20°, the surface reflection of the epidermis or the backscattered light from the measurement target portion (for example, blood vessels inside the skin) is detected by the light-receiving element 3.

As illustrated in FIGS. 23 and 24, when the incident angle θ is within the range of 43° < θ < 75°, the light L is totally reflected between the light guide film LG and the air interface, and directly emitted to the epidermis at a contact interface between the light guide film LG and the object to be detected FG. In this case, within the incident angle θ of 0° < θ < 75°, the first polarized light L1 and the second polarized light L2 are transmitted from the optical filter layer 50 into the object to be detected FG at transmittance Ts7 and Tp7, respectively, of substantially 100%. Transmittance Ts7 is a ratio of the first polarized light L1 transmitted from the optical filter layer 50 into the object to be detected FG. The transmittance Tp7 is a ratio of the second polarized light L2 transmitted from the optical filter layer 50 into the object to be detected FG.

In this case, when the magnitude of the acceptance angle of the optical filter layer 50 is within approximately 20°, the surface reflection of the epidermis or the backscattered light from the measurement target portion (for example, blood vessels inside the skin) is detected by the light-receiving element 3.

As illustrated in FIG. 23, the front light FL includes the light sources LS that emit the light L to the first side surface of the light guide film LG, and includes the reflector plate FL1 on the second side surface of the light guide film LG opposite the light sources LS and the third side surface orthogonal to side surfaces other than the first side surface for the light sources LS. The side surface of the reflector plate FL1 is inclined at an angle equal to or larger than the acceptance angle that is the maximum angle at which the light L enters the optical filter layer 50.

Thus, the light incident on the reflector plate FL1 can be reflected toward the side of the light source LS, thereby effectively using the light guided through the light guide film LG, and also improving the power efficiency of the detection device.

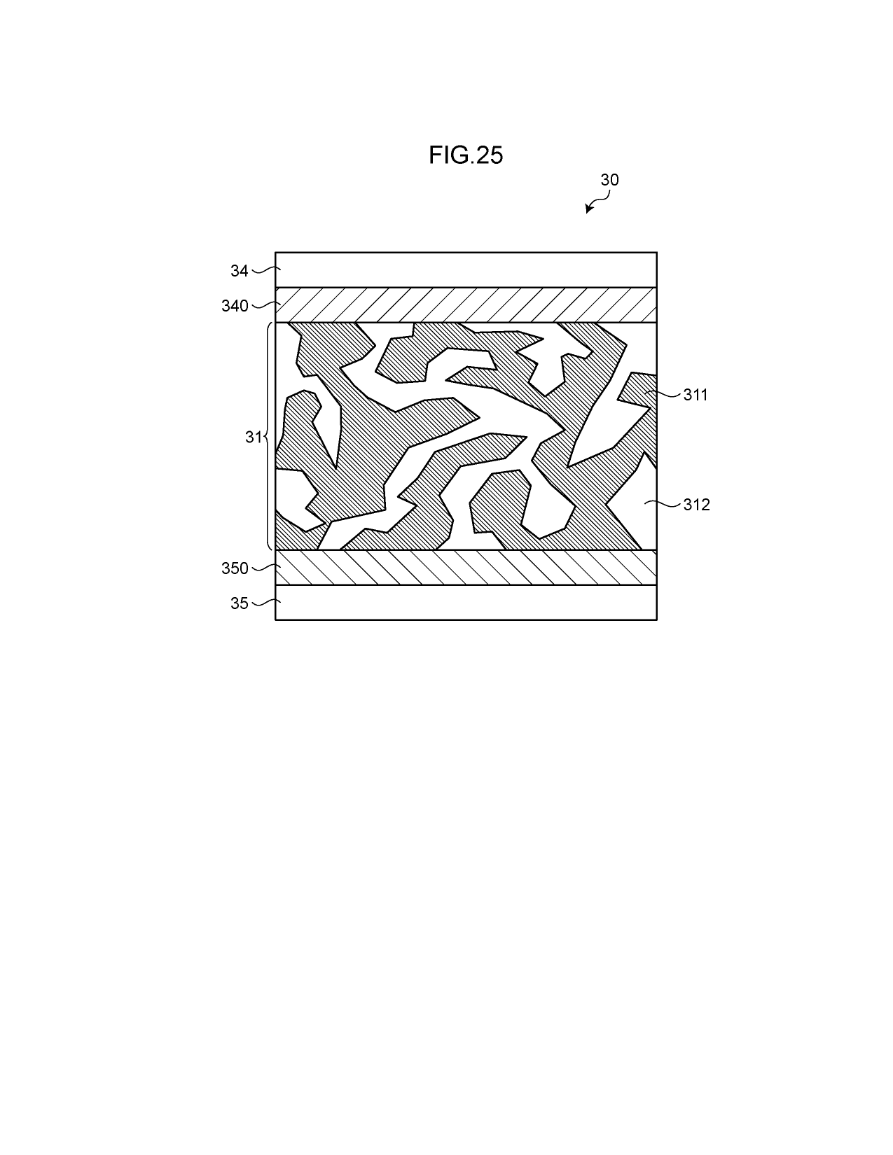

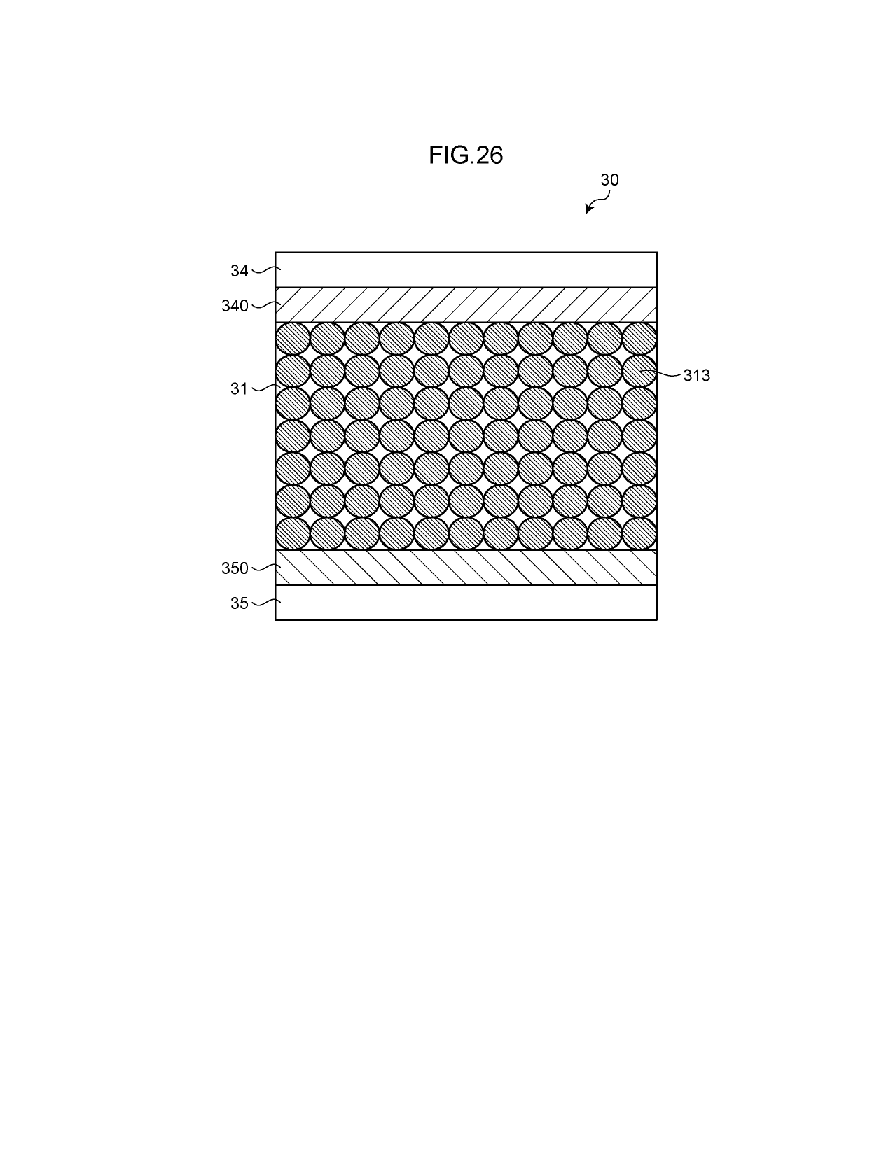

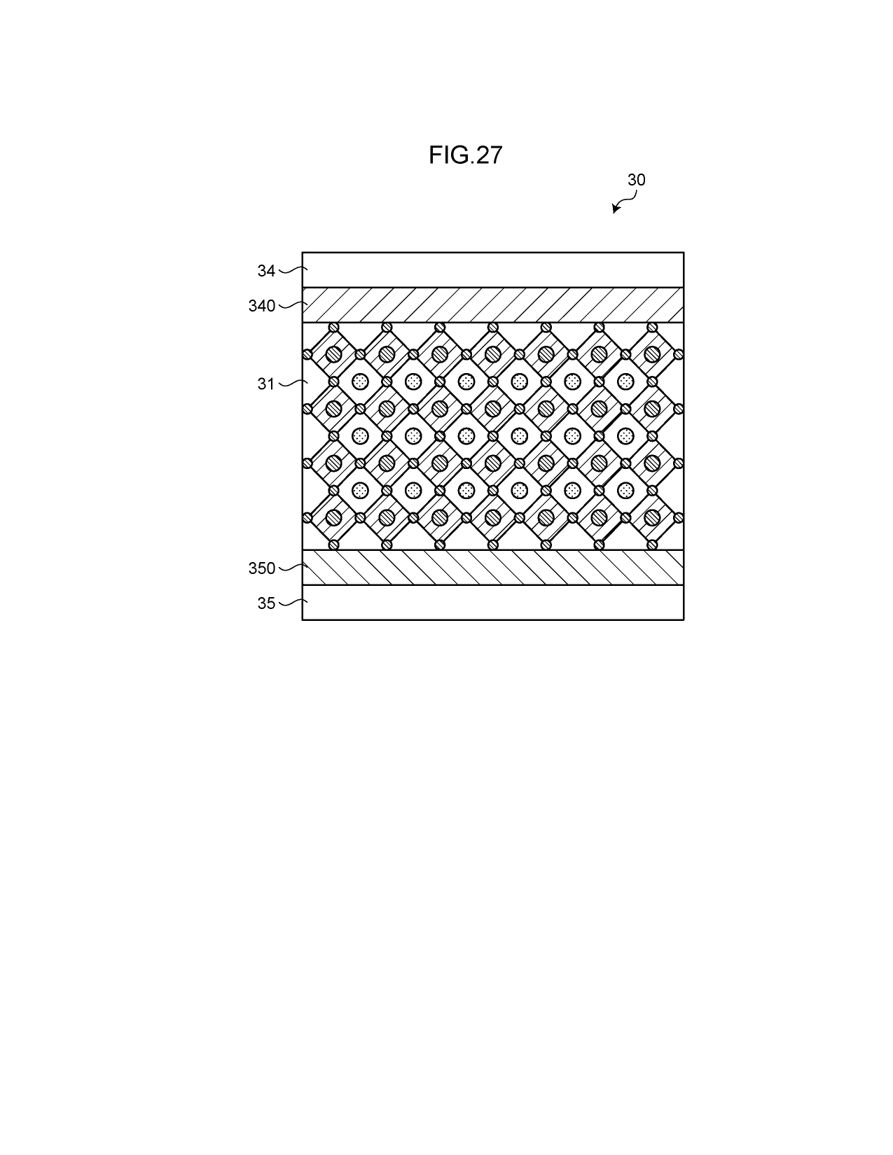

FIG. 25 is a sectional view schematically illustrating an example of the light-receiving element according to the eighth embodiment. FIG. 26 is a sectional view schematically illustrating a different example from the light-receiving element of FIG. 25. FIG. 27 is a sectional view schematically illustrating a different example from the light-receiving element of FIG. 26.

The photodiode 30 is an organic photodiode (OPD), quantum dots, or perovskite.

The photodiode 30 is an organic photodiode (OPD), for example. As illustrated in FIG. 25, the photodiode 30 include the lower electrode 35, a lower buffer layer 350, the semiconductor layer 31, an upper buffer layer 340, and the upper electrode 34. In the photodiode 30, the lower electrode 35, the lower buffer layer 350 (hole transport layer), the semiconductor layer 31, the upper buffer layer 340 (electron transport layer), and the upper electrode 34 are stacked in this order in the third direction Dz.

The lower electrode 35 may be an anode electrode of the photodiode 30, and the upper electrode 34 may be a cathode electrode of the photodiode 30. In that case, the lower buffer layer 350 may be a hole transport layer, and the upper buffer layer 340 may be an electron transport layer.

The semiconductor layer 31 contains acceptor molecules 311 and donor molecules 312. The semiconductor layer 31 has a bulk heterostructure in which the acceptor molecules 311 and the donor molecules 312 molecules are mixed together.

The photodiode 30 is the quantum dots, for example. As illustrated in FIG. 26, the semiconductor layer 31 contains quantum dots 313. The quantum dots 313 are nanosized semiconductor particles. For example, a main component of the core of the quantum dots is PbS, and the core is covered with ligands (coating layer) of, for example, oleic acid or polymer. The quantum dots 313 are arranged to form a quantum well structure.

The photodiode 30 is made of perovskite, for example. As illustrated in FIG. 27, the semiconductor layer 31 contains a transition metal oxide composed of a ternary system, such as a barium titanate (BaTiO₃), and forms a perovskite structure. The semiconductor layer 31 is, for example, a lead halide-based semiconductor (CH₃NH₃PbI₃), which is also a solar cell material.

### Ninth Embodiment

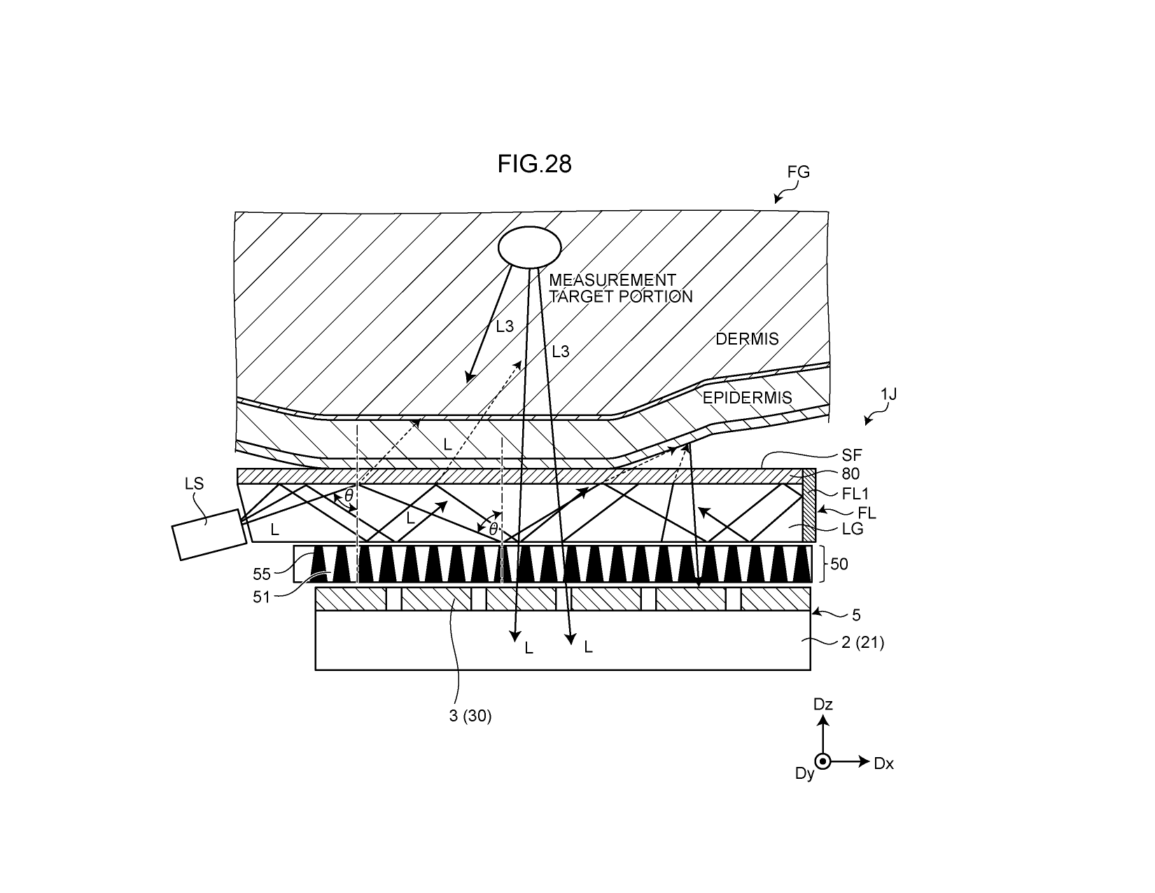

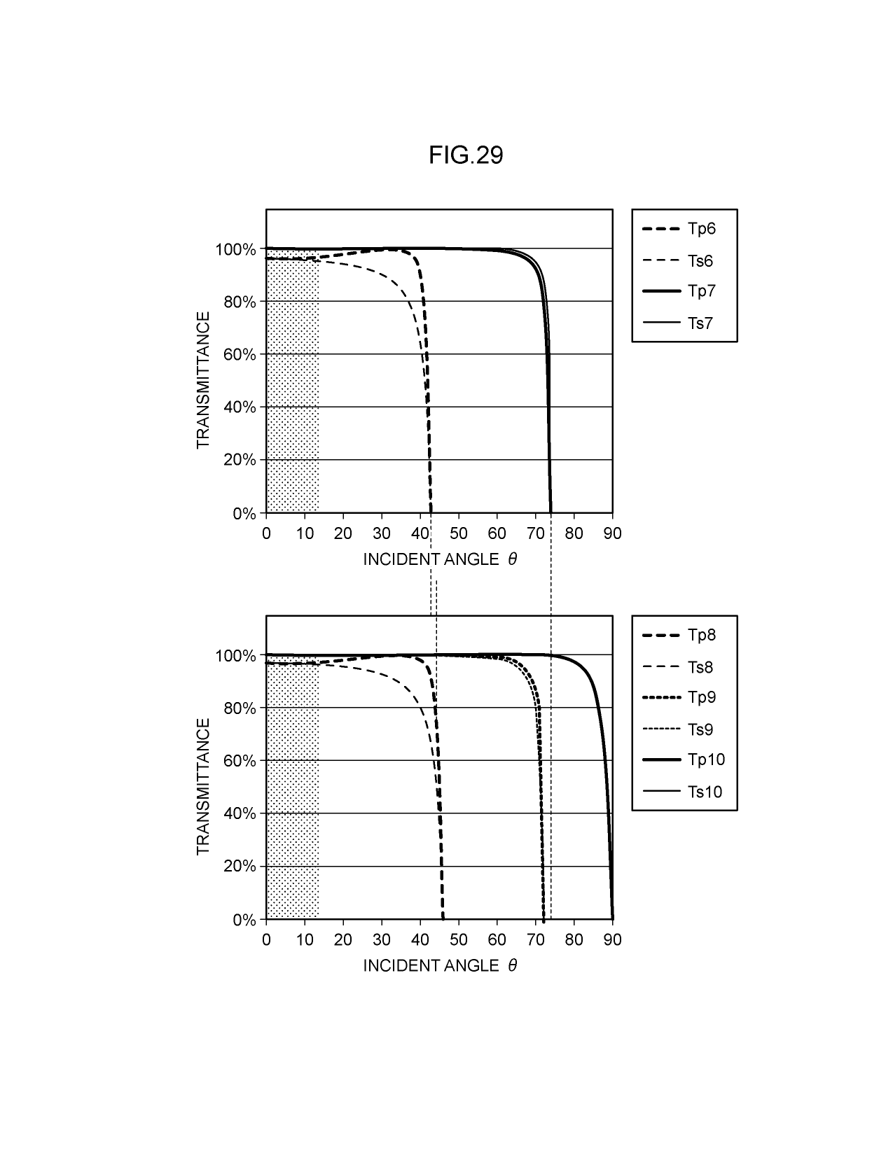

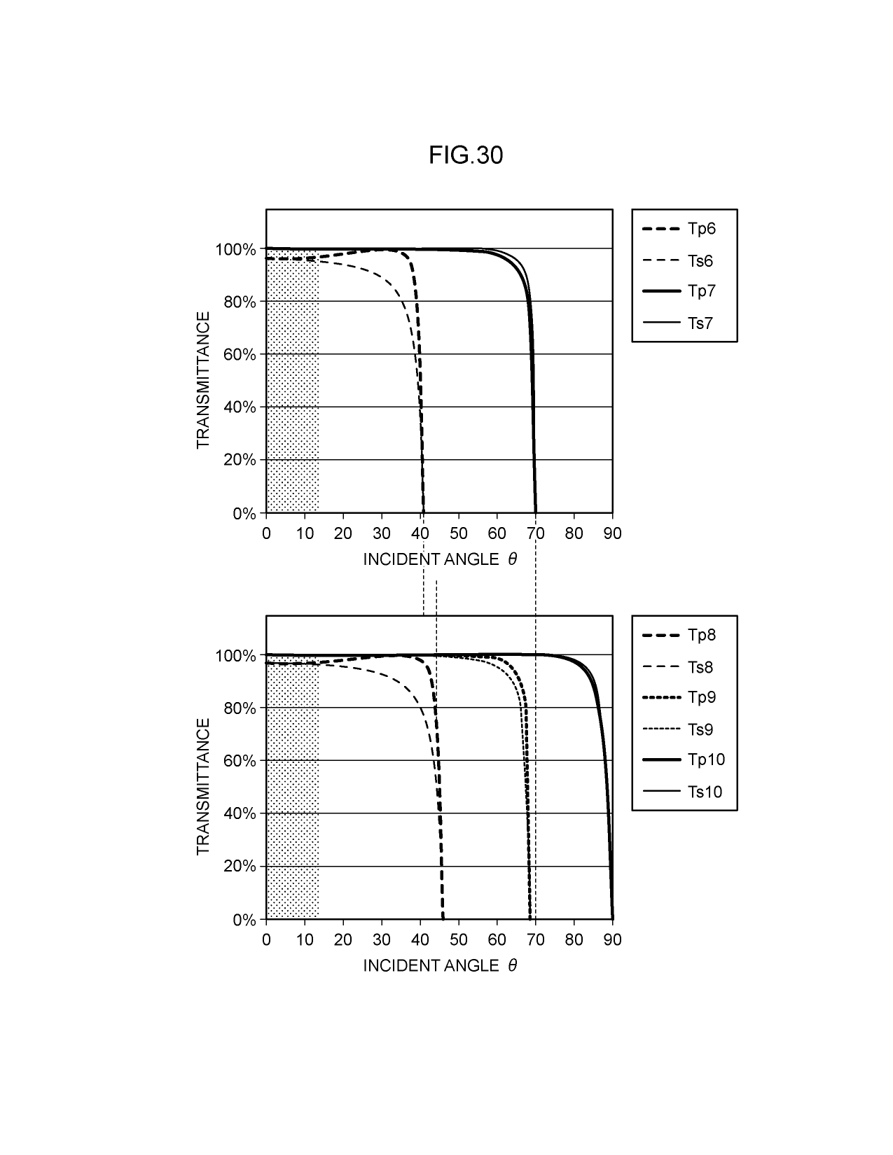

FIG. 28 is a sectional view schematically illustrating a section of a detection device according to a ninth embodiment of the present disclosure. FIG. 29 depicts explanatory diagrams illustrating a relation between the transmittance of the light guide film versus the incident angle and the transmittance of the protective film versus the incident angle in the ninth embodiment. FIG. 30 depicts explanatory diagrams explaining the transmittance of the light guide film versus the incident angle thereon, which is different from that of the detection device of FIG. 29. In the following description, the same components as those described in any one of the embodiments described above are denoted by the same reference numerals, and the description thereof will not be repeated.

As illustrated in FIG. 28, a detection device 1J according to the ninth embodiment includes the optical sensor 5, the front light FL, and the optical filter layer 50. The optical sensor 5, the optical filter layer 50, and the front light FL are stacked in this order on the substrate 21.

The front light FL includes the light sources LS that emit the light to the first side surface of the light guide film LG, and includes the light-transmitting protective film 80 on the detection surface SF side of the light guide film LG.

The following describes the case where the material of the light guide film LG is, for example, triacetylcellulose (TAC) and the material of the protective film 80 is, for example, polydimethylsiloxane (PDMS). In this case, the refractive index of the protective film 80 is, for example, 1.141, which is lower than the refractive index (1.487) of the light guide film LG. The refractive index of the protective film 80 is lower than the refractive index (1.43) of the epidermis of the object to be detected FG.

When the protective film 80 is not provided as illustrated in FIG. 29, the first polarized light L1 is transmitted through the light guide film LG at the transmittance Ts6 of 80% or more within the incident angle θ of 0° < θ < 43°, and the second polarized light L2 is transmitted through the light guide film LG at the transmittance Tp6 of substantially 100% and emitted to the epidermis of the object to be detected FG through the air interface or directly. In contrast, when the incident angle θ is within a range of 43° ≤ θ ≤ 75°, the light L is totally reflected between the light guide film LG and the air interface, and does not reach the epidermal interface of the object to be detected FG. When the light guide film LG is in contact with the epidermis of the object to be detected FG, the first polarized light L1 and the second polarized light L2 are transmitted through the light guide film LG at the transmittance Tp7 and Ts7 of substantially 100% within the range of 0° < θ < 75°, and the light reaches and enters the epidermal interface of the object to be detected FG.

In a case where the protective film 80 is provided on the detection surface SF side of the light guide film LG as illustrated in FIGS. 28 and 30, the light L is incident on the epidermal interface of the object to be detected FG through the air interface or directly when the incident angle θ at which the light L enters the protective film 80 is within the range of 0° < θ < 43°. In this case, the first polarized light L1 is transmitted through the protective film 80 at transmittance Ts8 of 80% or more, and the second polarized light L2 is transmitted through the protective film 80 at transmittance Tp8 of substantially 100%. The transmittance Ts8 is a ratio of the first polarized light L1 transmitted through the protective film 80. The transmittance Tp8 is a ratio of the second polarized light L2 transmitted through the protective film 80.

As illustrated in FIGS. 28 and 30, when the incident angle θ is in the range of 0° < θ < 75°, the light L is incident on the protective film 80 from the light guide film LG. In this case, within the incident angle θ of 0° < θ < 75°, the first polarized light L1 and the second polarized light L2 are transmitted from the light guide film LG to the protective film 80 at transmittance Tp9 and Ts9, respectively, of substantially 100%. The transmittance Ts9 is a ratio of the first polarized light L1 transmitted from the light guide film LG to the protective film 80. The transmittance Tp9 is a ratio of the second polarized light L2 transmitted from the light guide film LG to the protective film 80.

As illustrated in FIGS. 28 and 30, when the protective film 80 having a lower refractive index than the light guide film LG is provided, the light L is incident on the epidermal interface of the object to be detected FG that is in direct contact with the protective film 80, within the incident angle θ of 0° < θ < 90°. In this case, within the incident angle θ of 75° < θ < 80°, the first polarized light L1 and the second polarized light L2 are transmitted from the protective film 80 into the object to be detected FG at transmittance Tp10 and Ts10, respectively, of substantially 100%. The transmittance vales Ts10 and Tp10 are ratios of the first polarized light L1 and the second polarized light L2, respectively, transmitted from the protective film 80 into the object to be detected FG.

Thus, as illustrated in FIGS. 29 and 30, the incident angle θ of light from the protective film 80 to the epidermal surface of the object to be detected FG in contact with the protective film 80 increases from 75° to 90°. As a result, the efficiency of guiding the light to the optical sensor 5 can be improved. When curvature is generated by winding the light guide film around the wrist or the like, the incident angle θ on the inner diameter side of the light guide film effectively becomes larger, which is effective in maintaining the amount of light incident on the object to be detected FG when the protective film 80 having a lower refractive index is present.

### Tenth Embodiment

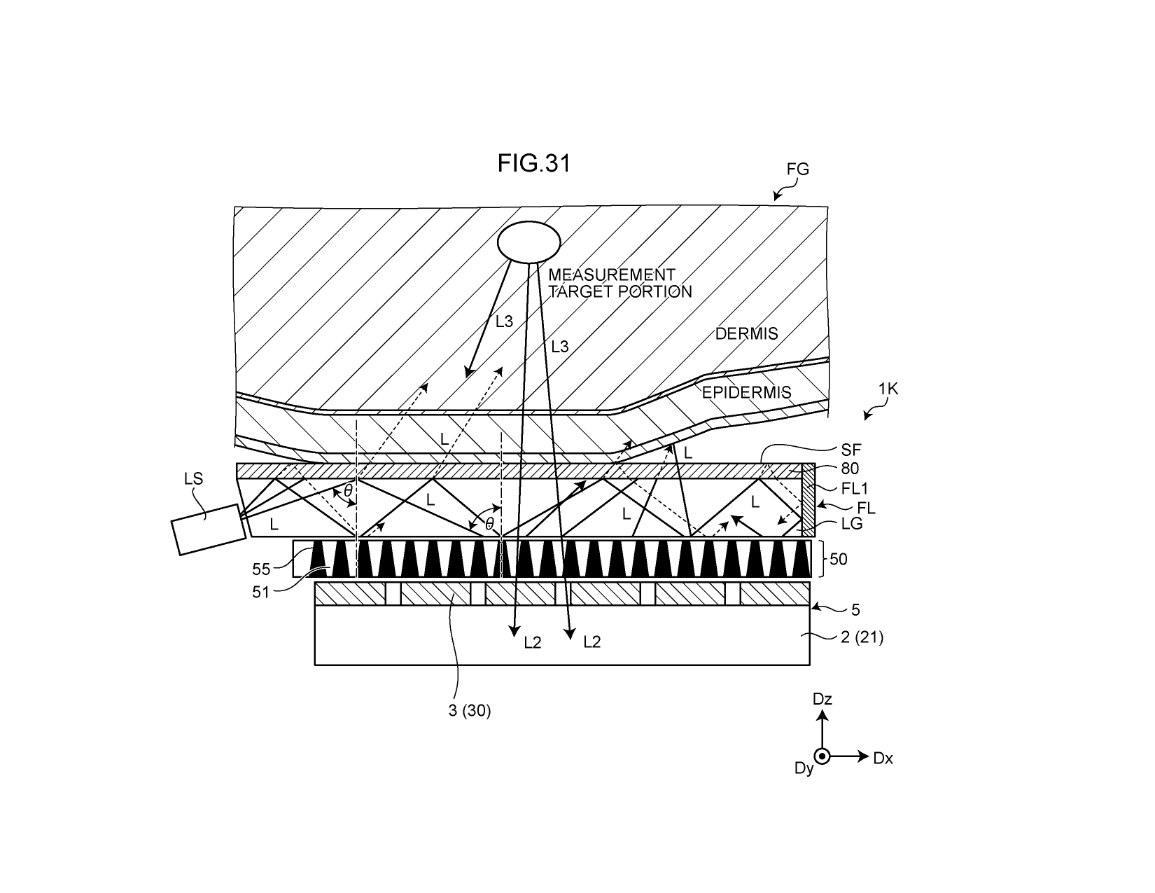

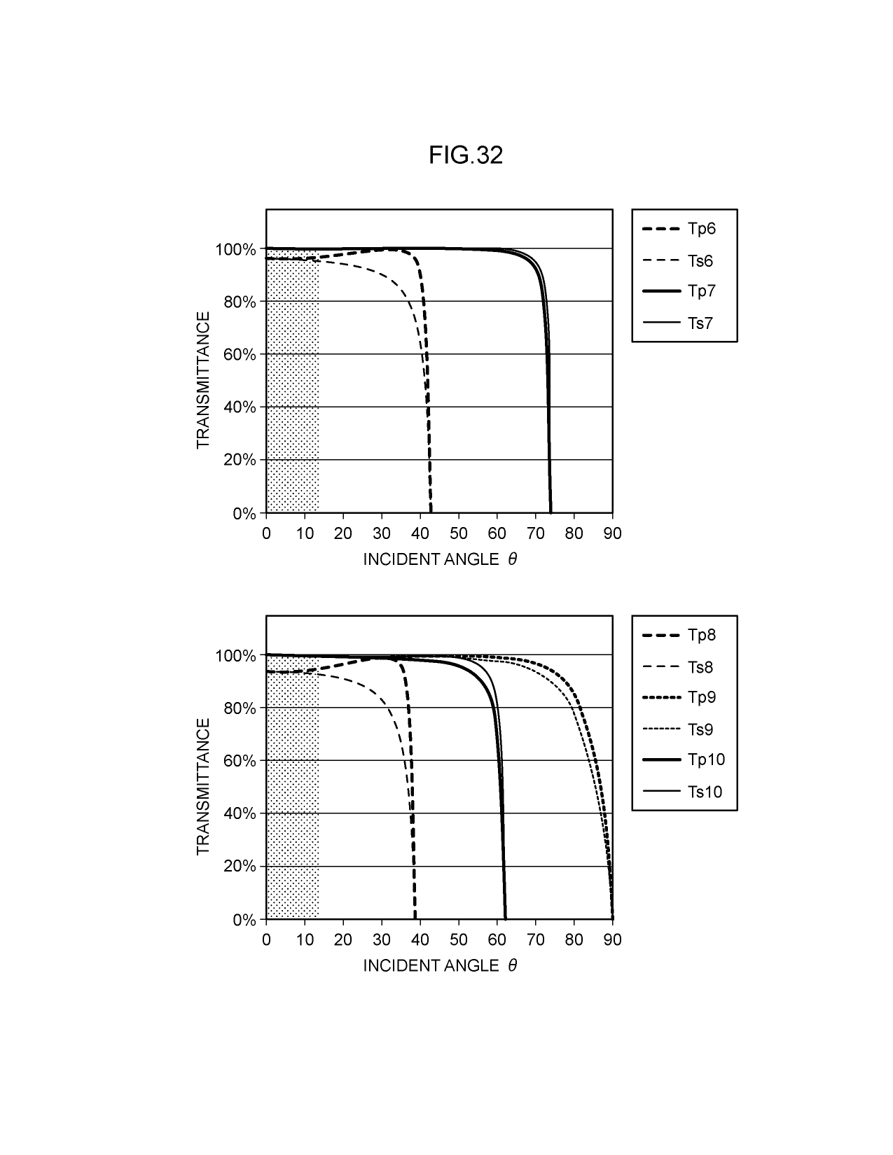

FIG. 31 is a sectional view schematically illustrating a detection device according to a tenth embodiment of the present disclosure. FIG. 32 depicts explanatory diagrams illustrating a relation between the transmittance of the light guide film versus the incident angle and the transmittance of the protective film versus the incident angle in the tenth embodiment. In the following description, the same components as those described in any one of the embodiments described above are denoted by the same reference numerals, and the description thereof will not be repeated.

In a detection device 1K according to the tenth embodiment, the following describes a case where the material of the light guide film LG is, for example, triacetylcellulose (TAC) and the material of the protective film 80 is, for example, polyethylene terephthalate (PET). In this case, the refractive index of the protective film 80 is, for example, 1.63, which is higher than the refractive index (1.487) of the light guide film LG. The refractive index of the protective film 80 is also higher than that of the epidermis of the object to be detected FG (1.43).

As illustrated in FIGS. 31 and 32, when the incident angle θ at which the light L enters the protective film 80 is within the range of 0° < θ < 38°, the light L is incident on the epidermal interface of the object to be detected FG through the air interface or directly. When the incident angle θ is in a range of 38° < θ < 62°, the light L is totally reflected between the protective film 80 and the air interface, and does not reach the epidermal interface of the object to be detected FG. When the incident angle θ is within a range of 62° < θ < 90°, the light L enters the protective film 80 from the light guide film LG.

As illustrated in FIGS. 31 and 32, the incident angle θ onto the epidermal surface of the object to be detected FG decreases from 75° to 62°. In this case, when the light L travels from the light guide film LG toward the protective film 80, the light L travels from a medium having a lower refractive index to a medium having a higher refractive index. Therefore, the light L can more easily enter the skin by an extent of the reduction of the incident angle θ. As a result, the surface reflection components from the skin surface that are a cause of noise can be reduced.

When the light L travels from the protective film 80 toward the epidermis of the object to be detected FG, the light L travels from a medium having a higher refractive index to a medium having a lower refractive index. Therefore, when the incident angle θ is larger than the critical angle, the light L is totally reflected on the surface of the protective film 80, and the ratio of the light guided to the entire surface of the optical sensor 5 increases.

When the light guide film LG is used by being wound around the wrist or the like and becomes curved, the incident angle θ of light on the inner diameter side of the light guide film LG increases, but the incident angle θ of light incident onto the epidermal surface of the object to be detected FG through the air interface decreases. Therefore, the angle range of light irradiation to the epidermis is narrowed, which can reduce the surface reflection components from the skin surface that are a cause of noise.

### Eleventh Embodiment

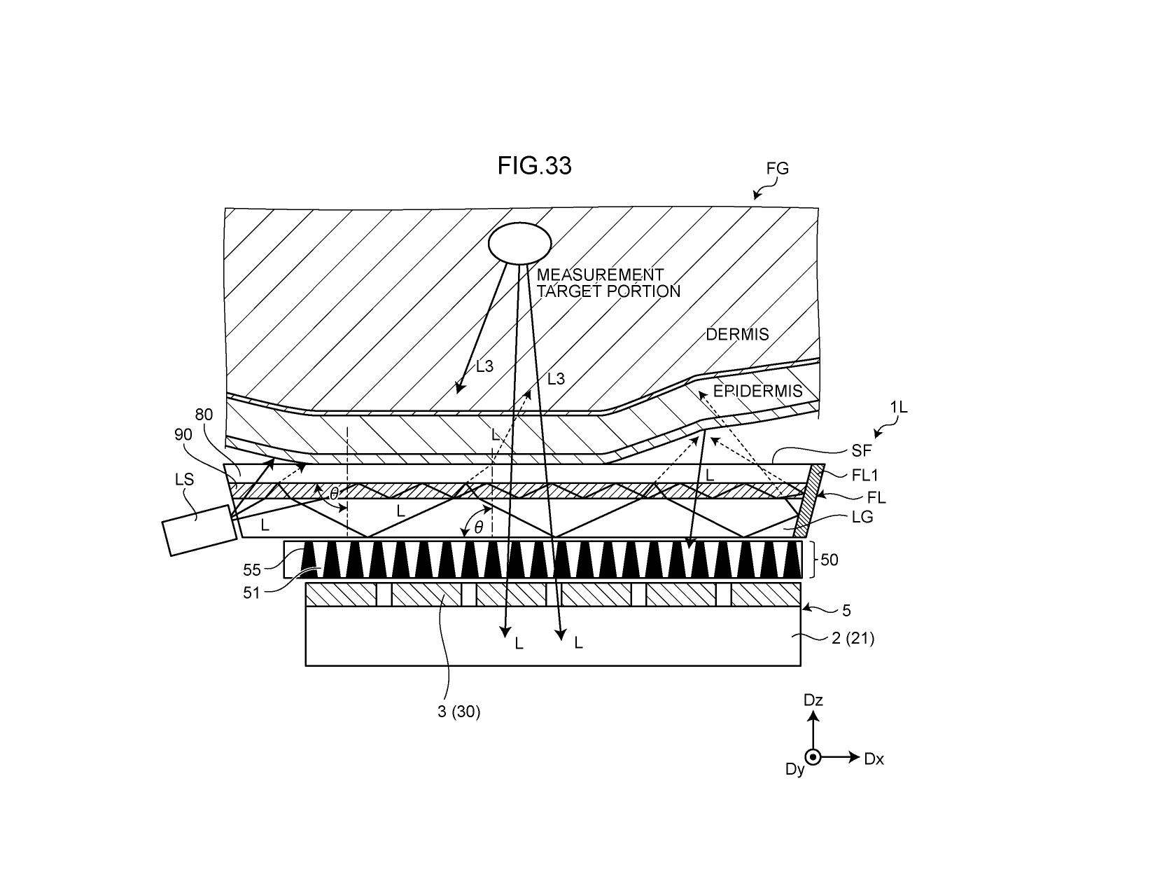

FIG. 33 is a sectional view schematically illustrating a detection device according to an eleventh embodiment of the present disclosure. In the following description, the same components as those described in any one of the embodiments described above are denoted by the same reference numerals, and the description thereof will not be repeated.

As illustrated in FIG. 33, a detection device 1L according to the eleventh embodiment includes the high refractive index waveguide layer 90 on the SF side of the light guide film LG. The high refractive index waveguide layer 90 is located between the protective film 80 and the light guide film LG.

Thus, the light can be uniformly emitted to the entire surface of the optical sensor 5, and the detection accuracy can be improved.

As illustrated in FIG. 33, the inclination angle of the side surface of the light guide film LG on which the light L is incident is at an angle other than 90° with respect to the detection surface SF of the light guide film LG. In this case, the side surface of the light guide film LG is inclined with respect to the detection surface SF of the light guide film LG facing the object to be detected FG, and the light source LS faces the inclined side surface of the light guide film LG.

This configuration can reduce the loss of the light incident from the light source LS and can improve the efficiency of light guide to the light guide film LG. The light emission intensity of the light source LS can be increased, and power consumption can be reduced.

### Twelfth Embodiment

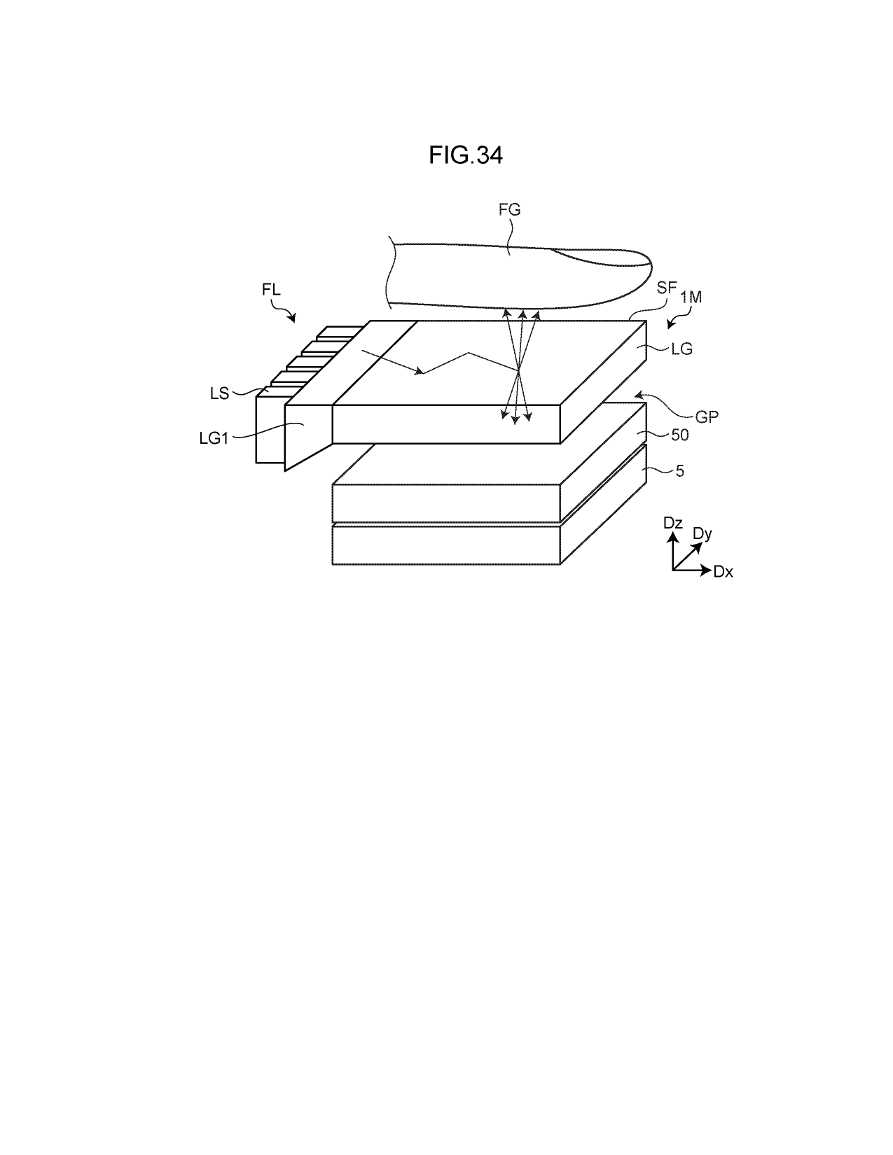

FIG. 34 is a perspective view schematically illustrating a detection device according to a twelfth embodiment of the present disclosure. In the following description, the same components as those described in any one of the embodiments described above are denoted by the same reference numerals, and the description thereof will not be repeated.

As illustrated in FIG. 34, a detection device 1M according to the twelfth embodiment includes the optical sensor 5, the front light FL, and the optical filter layer 50. The optical sensor 5, the optical filter layer 50, and the front light FL are stacked in this order on the substrate 21.

The gap GP is provided between the light guide film LG and the optical filter layer 50. The light guide film LG is bonded to the optical filter layer 50, for example, with an optical resin (not illustrated) in the gap GP. The gap GP may be an air layer, for example.

As illustrated in FIG. 34, the shape of the light entrance LG1 provided on the side surface side of the light guide film LG on which the light L of the light guide film LG is incident is trapezoidal in sectional view in the plane orthogonal to the second direction Dy (Dx-Dz plane).

The operations and effects of the detection device 1M according to the twelfth embodiment are the same as those of the detection device 1F of the fifth embodiment, and therefore, will not be described in detail.

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure.

For example, any combination of the aspects of the first to the twelfth embodiments naturally falls within the technical scope of the present disclosure.

What is claimed is:

1. A detection device comprising:
an optical sensor comprising a plurality of light-receiving elements configured to receive light; and
a front light that is located on an object to be detected side of the optical sensor and comprises a light guide film and a plurality of light sources configured to emit light to a first side surface of the light guide film, wherein
a wire-grid polarizer configured to separate the light incident from the light source into first polarized light and second polarized light is located between the optical sensor and the front light.

2. The detection device according to claim 1, wherein
the light guide film is configured to propagate one of the first polarized light and the second polarized light, and
the light guide film is configured to transmit and emit the other of the first polarized light and the second polarized light toward the optical sensor.

3. The detection device according to claim 1, wherein an optical filter layer is located between the wire-grid polarizer and the light-receiving elements.

4. The detection device according to claim 3, wherein a light-transmitting protective film is located on a detection surface on the object to be detected side of the light guide film.

5. The detection device according to claim 4, wherein a refractive index of the protective film is higher than a refractive index of the light guide film.

6. The detection device according to claim 5, wherein each of the light-receiving elements is an organic photodiode.

7. The detection device according to claim 6, wherein
the light source comprises first light sources and second light sources,
the first light sources and the second light sources are alternately arranged,
the first light sources and the second light sources are each configured to emit at least one of infrared light, near-infrared light, red light, and green light, and
a wavelength of the light of the first light sources differs from a wavelength of the light of the second light sources.

8. The detection device according to claim 7, wherein a plurality of the light sources are arranged on two orthogonal sides, two opposed sides, or three sides of the light guide film.

9. The detection device according to claim 7, comprising a light entrance on a side surface side of the light guide film on which light of the light guide film is incident, wherein
the light entrance has a trapezoidal shape in sectional view.

10. The detection device according to claim 7, wherein
a side surface of the light guide film is inclined with respect to a normal direction of the detection surface on the object to be detected side of the light guide film, and
the light source faces the side surface.

11. The detection device according to claim 7, comprising, on the detection surface side of the light guide film, a high refractive index waveguide layer that has a higher refractive index than the refractive index of the light guide film and the refractive index of the protective film, wherein
the high refractive index waveguide layer is located between the protective film and the light guide film.

12. The detection device according to claim 7, wherein
the front light comprises a reflector plate on a side surface opposite a side surface of the light guide film facing the light source, and
a side surface of the reflector plate is inclined at an angle equal to or larger than an acceptance angle that is a maximum angle at which light enters the optical filter layer.

13. A detection device comprising:
an optical sensor comprising a plurality of light-receiving elements configured to receive light;
a front light that is located on an object to be detected side of the optical sensor and comprises a light guide film; and
an optical filter layer located between the optical sensor and the front light, wherein
the optical sensor, the optical filter layer, and the front light are stacked in the order as listed, and
the front light comprises a plurality of light sources configured to emit light to a first side surface of the light guide film, and comprises a reflector plate on a second side surface of the light guide film opposite the light sources.

14. The detection device according to claim 13, wherein the second side surface is inclined at an angle equal to or larger than an acceptance angle that is a maximum angle at which light enters the optical filter layer.

15. The detection device according to claim 13, wherein each of the light-receiving elements is at least one of an organic photodiode, quantum dots, and perovskite.

16. A detection device comprising:
an optical sensor comprising a plurality of light-receiving elements configured to receive light;
a front light that is located on an object to be detected side of the optical sensor and comprises a light guide film; and
an optical filter layer located between the optical sensor and the front light, wherein the optical sensor, the optical filter layer, and the front light are stacked in the order as listed, and
the front light comprises a plurality of light sources configured to emit light to a first side surface of the light guide film, and
a light-transmitting protective film is provided on a detection surface side of the light guide film.

17. The detection device according to claim 16, wherein a refractive index of the protective film is higher than a refractive index of the light guide film.

18. The detection device according to claim 16, comprising, on the detection surface side of the light guide film, a high refractive index waveguide layer that has a higher refractive index than the refractive index of the light guide film and the refractive index of the protective film, wherein
the high refractive index waveguide layer is located between the protective film and the light guide film.

19. A detection device comprising:
an optical sensor comprising a plurality of light-receiving elements configured to receive light;
a front light that is located on an object to be detected side of the optical sensor and comprises a light guide film; and
an optical filter layer located between the optical sensor and the front light, wherein the optical sensor, the optical filter layer, and the front light are stacked in the order as listed, and
an inclination angle of a side surface of the light guide film on which light is incident is at an angle other than 90° with respect to a detection surface of the light guide film.

20. A detection device comprising:
an optical sensor comprising a plurality of light-receiving elements configured to receive light;
a front light that is located on an object to be detected side of the optical sensor and comprises a light guide film and a plurality of light sources configured to emit light to a first side surface of the light guide film; and
an optical filter layer located between the optical sensor and the front light, wherein
the optical sensor, the optical filter layer, and the front light are stacked in the order as listed,
the detection device comprises a light entrance on a side surface side of the light guide film on which light of the light guide film is incident, and
the light entrance has a trapezoidal shape in sectional view.
